(19) United States
(12) Patent Application Publication
(10) Pub. No.: US 2024/0324301 A1
(43) Pub. Date: Sep. 26, 2024

(54) DISPLAY APPARATUS

(71) Applicant: Samsung Display Co., Ltd., Yongin-si (KR)

(72) Inventors: Subin Bae, Yongin-si (KR); Woongsik Kim, Yongin-si (KR); Duckjung Lee, Yongin-si (KR); Chulmin Bae, Yongin-si (KR)

(73) Assignee: Samsung Display Co., Ltd., Yongin-si (KR)

(21) Appl. No.: 18/438,027

(22) Filed: Feb. 9, 2024

(30) Foreign Application Priority Data
Mar. 24, 2023 (KR) 10-2023-0039237
Jun. 23, 2023 (KR) 10-2023-0081336

(51) Int. Cl. H10K 59/122; H10K 59/35

(52) U.S. Cl. CPC H10K 59/122; H10K 59/35

(57) ABSTRACT

A display apparatus includes a substrate, a first subpixel electrode and a second subpixel electrode spaced apart from each other and disposed on the substrate, a subpixel-defining layer disposed on the substrate and including openings that expose respective central portions of the first subpixel electrode and the second subpixel electrode, respectively, and a trench disposed between the first subpixel electrode and the second subpixel electrode in plan view, an electrode layer disposed in the trench to be spaced apart from side surfaces of the trench, and a redistribution layer RE disposed between the electrode layer and the side surfaces of the trench to expose at least a portion of the electrode layer.

### CROSS-REFERENCE TO RELATED APPLICATION(S)

This application claims priority under 35 U.S.C. § 119 to and benefits of Korean Patent Application No. 10-2023-0039237, filed on Mar. 24, 2023, and Korean Patent Application No. 10-2023-0081336, filed on Jun. 23, 2023, in the Korean Intellectual Property Office, the entire contents of which are incorporated herein by reference.

### BACKGROUND

### 1. Technical Field

One or more embodiments relate to a display apparatus. More particularly, one or more embodiments relate to a display apparatus capable of preventing lateral leakage of a current by disconnecting a charge generation layer by using Joule-heating wires.

### 2. Description of the Related Art

Display apparatuses receive image data and display an image corresponding to the image data. Subpixels of a display apparatus may have a tandem structure including emission layers. A charge generation layer may be disposed between the emission layers to increase light-emitting efficiency. Because the charge generation layer have conductivity, a current may flow in an unintended direction (e.g., sideways). The lateral leakage of the current may cause color mixing between adjacent subpixels.

### SUMMARY

In order to prevent lateral leakage of a current, a charge generation layer may be disconnected in a space between adjacent subpixels. A method of removing a portion of the charge generation layer disposed on a joule-heating wire by using heat generated by applying a voltage to the joule-heating wire after depositing the charge generation layer by arranging the joule-heating wire may be used as a disconnection method. However, materials of the charge generation layer removed by heating may accumulate around wiring. This may cause thickness non-uniformity of a subpixel-stacked structure, and may lead to subpixel defects and luminance defects.

Embodiments provide a display apparatus capable of preventing lateral leakage of a current by disconnecting a charge generation layer by using Joule-heating wires.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, a display apparatus may include a substrate, a first subpixel electrode and a second subpixel electrode spaced apart from each other and disposed on the substrate, a subpixel-defining layer disposed on the substrate and including openings that expose respective central portions of the first subpixel electrode and the second subpixel electrode, respectively, and a trench disposed between the first subpixel electrode and the second subpixel electrode in plan view, an electrode layer disposed in the trench to be spaced apart from side surfaces of the trench, and a redistribution layer disposed between the electrode layer and the side surfaces of the trench to expose at least a portion of the electrode layer.

The display apparatus may further include a plurality of emitting units disposed on the first subpixel electrode and the second subpixel electrode.

At least one of the plurality of emitting units may include a first functional layer, a second functional layer, and emission layers disposed between the first functional layer and the second functional layer.

At least one of the plurality of emitting units may be connected in a region overlapping the trench.

The display apparatus may further include one or more charge generation layers disposed between the plurality of emitting units.

The charge generation layer may be disconnected in a region overlapping the trench.

The charge generation layer may include a negative charge generation layer and a positive charge generation layer.

The display apparatus may further include an opposite electrode disposed on the plurality of emitting units.

The subpixel-defining layer may include a tip portion protruding toward the trench.

The width of the trench may decrease in a direction.

The trench may surround each subpixel electrode in plan view.

According to one or more embodiments, a display apparatus may include a substrate, a first subpixel electrode and a second subpixel electrode spaced apart from each other on the substrate, a subpixel-defining layer disposed on the substrate and including openings exposing respective central portions of the first subpixel electrode and the second subpixel electrode, respectively, and a trench TR disposed between the first subpixel electrode and the second subpixel electrode in plan view, an organic insulating layer disposed between the substrate and the subpixel-defining layer and including an opening overlapping the trench, an electrode layer disposed in the openings to be spaced apart from side surfaces of the openings, and a redistribution layer disposed between the electrode layer and the side surfaces of the openings to expose at least a portion of the electrode layer, wherein the trench may pass through the subpixel-defining layer.

According to one or more embodiments, a display apparatus includes a substrate, a plurality of subpixel electrodes spaced apart from each other and disposed on the substrate, a subpixel-defining layer disposed on the substrate and including a plurality of openings respectively corresponding to the plurality of subpixel electrodes, an emission element unit including a plurality of emission elements disposed on the plurality of subpixel electrodes, and an electrode layer disposed on the subpixel-defining layer. The emission element unit includes a plurality of layers, and at least one of the plurality of layers may partially overlap the electrode layer in plan view, and at least one of the plurality of layers may have an opening exposing at least a portion of the electrode layer to the outside.

One of the plurality of layers of one of the plurality of emission elements may be separated from one of the plurality of layers of another one of the plurality of emission elements.

One of the plurality of layers of one of the plurality of emission elements may be connected to one of the plurality of layers of another one of the plurality of emission elements in a region overlapping the electrode layer.

The plurality of layers of the emission element unit may be spaced apart from the electrode layer.

The display apparatus may further include a redistribution layer that covers at least a portion of side surfaces of the electrode layer and exposes at least a portion of an upper surface of the electrode layer.

The subpixel-defining layer may include a trench, and the electrode layer may be disposed in the trench of the subpixel-defining layer.

The electrode layer may surround the plurality of emission elements of the emission element unit.

The display apparatus may further include an opposite electrode disposed on the emission element unit and the electrode layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is a schematic cross-sectional view of a portion of a display apparatus according to an embodiment;

FIG. 3 is a magnified schematic cross-sectional view of a portion of a display apparatus according to an embodiment;

FIG. 4A is a magnified schematic cross-sectional view of region A of FIG. 3;

FIG. 4B is a schematic cross-sectional view of a light-emitting diode (LED) of FIG. 4A;

FIG. 5 is a magnified schematic cross-sectional view of a portion of a display apparatus according to an embodiment;

FIG. 6A is a magnified schematic plan view of a portion of a display area of a display apparatus according to an embodiment;

FIG. 6B is a magnified schematic plan view of region B of FIG. 6A;

FIGS. 7A, 7B, 7C, 7D, 7E, 7F, 7G, 7H, 7I, and 7J are schematic cross-sectional views illustrating a manufacturing method according to an embodiment;

FIG. 8 is a magnified schematic cross-sectional view of a portion of a display apparatus according to an embodiment;

FIGS. 9A, 9B, 9C, 9D, 9E, 9F, 9G, 9H, 9I, and 9J are schematic cross-sectional views illustrating a manufacturing method according to an embodiment;

FIG. 10 is a magnified schematic cross-sectional view of a portion of a display apparatus according to an embodiment;

FIG. 11 is a magnified schematic cross-sectional view of a portion of a display apparatus 1 according to an embodiment; and

FIG. 12 is a magnified schematic cross-sectional view of a portion of a display apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the x-axis, the y-axis, and the z-axis are not limited to three axes of a rectangular coordinate system, such as the x, y, and z axes, and may be interpreted in a broader sense. For example, the z-axis, the y-axis, and the z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

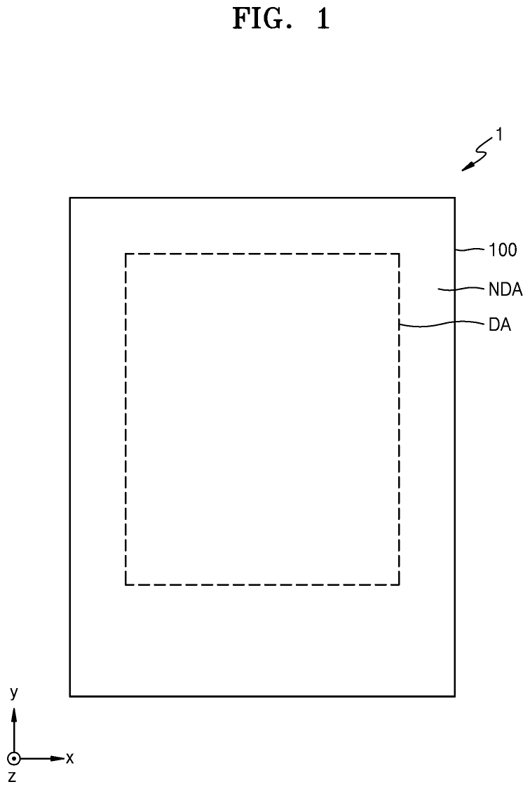

FIG. 1 is a schematic plan view of a display apparatus 1 according to an embodiment.

Referring to FIG. 1, the display apparatus 1 may include a substrate 100 including a display area DA and a non-display area NDA. Subpixels including display elements such as light-emitting diodes may be disposed in the display area DA to display an image. The non-display area NDA may not provide an image and may surround the display area DA. A scan driver and a data driver, which provide electrical signals to be applied to the subpixels of the display area DA, and power lines, which provide power such as a driving voltage and a common voltage, may be disposed in the non-display area NDA.

In FIG. 1, a length of the display apparatus 1 in an x-axis direction may be less than a length of the display apparatus 1 in a y-axis direction intersecting the x-axis direction. However, embodiments are not limited thereto. In another example, the length of the display apparatus 1 in the x-axis direction may be greater than the length of the display apparatus 1 in the y-axis direction. In this way, the shape of the display apparatus 1 may be variously changed.

The display apparatus 1 may be applicable to various products, such as mobile phones, smartphones, tablet personal computers (PCs), mobile communication terminals, electronic notebooks, electronic books, portable multimedia players (PMPs), navigation devices, ultra mobile PCs (UMPCs), televisions, notebooks, monitors, advertisement panels, and Internet of Things (IoT). The display apparatus 1 according to an embodiment may be also applicable to wearable devices, such as smart watches, watch phones, glasses-type displays, and head mounted displays (HMDs). The display apparatus 1 according to an embodiment may be also applicable to dashboards of automobiles, center information displays (CIDs) of the center fasciae or dashboards of automobiles, room mirror displays that replace the side mirrors of automobiles, and displays arranged on the rear sides of front seats to function as entertainment devices for back seat passengers of automobiles.

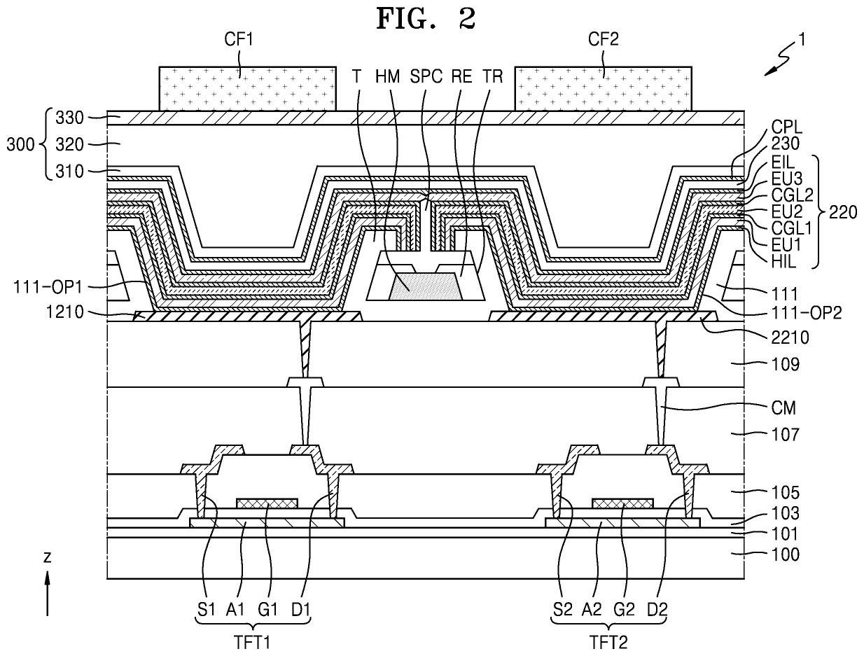

FIG. 2 is a schematic cross-sectional view of a portion of the display apparatus 1 according to an embodiment.

Referring to FIG. 2, first and second subpixel electrodes 1210 and 2210 corresponding to subpixels disposed in a display area DA may be disposed on the substrate 100. The first and second subpixel electrodes 1210 and 2210 may be connected (e.g., electrically connected) to first and second thin film transistors TFT1 and TFT2, respectively.

The first and second thin film transistors TFT1 and TFT2 may include active layers A1 and A2, gate electrodes G1 and G2 overlapping partial regions of the active layers A1 and A2, and source electrodes S1 and S2 and drain electrodes D1 and D2 connected to the active layers A1 and A2. The gate electrodes G1 and G2 may include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and may have a single-layered structure or a multi-layered structure including the aforementioned material.

A buffer layer 101 for preventing penetration of impurities may be interposed between the active layers A1 and A2 and the substrate 100. A gate insulating layer 103 may be interposed between the active layers A1 and A2 and the gate electrodes G1 and G2. An interlayer insulating layer 105 may be arranged on the gate electrodes G1 and G2. The buffer layer 101, the gate insulating layer 103, and the interlayer insulating layer 105 may each include an inorganic insulating material, such as silicon oxide (SiOₓ), silicon nitride (SiNₓ), silicon oxynitride (SiOₓN_{y}), aluminum oxide (AlOₓ), aluminum nitride (AlNₓ), titanium oxide (TiOₓ), or titanium nitride (TiNₓ), but embodiments are not limited thereto.

The source electrodes S1 and S2 and the drain electrodes D1 and D2 may be positioned on the interlayer insulating layer 105, and may be connected to the active layers A1 and A2 through a contact hole formed in the interlayer insulating layer 105 and the gate insulating layer 103. The source electrodes S1 and S2 and the drain electrodes D1 and D2 may each include at least one selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may each have a single-layered structure or a multi-layered structure.

A first organic insulating layer 107 may be disposed on the first and second thin film transistors TFT1 and TFT2. The first organic insulating layer 107 may include an organic insulating material such as acrylic, benzocyclobutene (BCB), polyamide (PI), or hexamethyldisiloxane (HMDSO), but embodiments are not limited thereto.

A connection metal CM may be disposed on the first organic insulating layer 107. The connection metal CM may include Al, Cu, and/or Ti, and may be a multi-layer or a single layer including the aforementioned materials.

A second organic insulating layer 109 may be disposed between the connection metal CM and the first and second subpixel electrodes 1210 and 2210. The second organic insulating layer 109 may include an organic insulating material such as acrylic, benzocyclobutene (BCB), polyamide (PI), or hexamethyldisiloxane (HMDSO), but embodiments are not limited thereto. According to the embodiment described above with reference to FIG. 2, the first and second thin film transistors TFT1 and TFT2 and the first and second subpixel electrodes 1210 and 2210 may be connected (e.g., electrically connected) to each other through the connection metal CM. However, according to another example, the connection metal CM may be omitted, and an organic insulating layer (e.g., a single organic insulating layer) may be positioned between the first and second thin film transistors TFT1 and TFT2 and the first and second subpixel electrodes 1210 and 2210. In another example, three or more organic insulating layers may be positioned between the first and second thin film transistors TFT1 and TFT2 and the first and second subpixel electrodes 1210 and 2210, and the first and second thin film transistors TFT1 and TFT2 and the first and second subpixel electrodes 1210 and 2210 may be connected (e.g., electrically connected) to each other through connection metals.

The first and second subpixel electrodes 1210 and 2210 may be disposed on the second organic insulating layer 109. The first and second subpixel electrodes 1210 and 2210 may be formed to be reflective electrodes. In the first and second subpixel electrodes 1210 and 2210, a reflective layer may be formed of silver (Ag), magnesium (Mg), aluminum (Al), platinum (Pt), palladium (Pd), gold (Au), nickel (Ni), neodymium (Nd), iridium (Ir), chromium (Cr), or a compound thereof, and a layer formed of indium tin oxide (ITO), indium zinc oxide (IZO), ZnO, or In₂O₂ may be disposed on the reflective layer. According to an embodiment, the first and second subpixel electrodes 1210 and 2210 may each have a structure in which an ITO layer, an Ag layer, and an ITO layer are sequentially stacked. For example, embodiments are not limited thereto, and the first and second subpixel electrodes 1210 and 2210 may include any of various other materials and may have any of various structures, such as, a single-layered structure or a multi-layered structure. The first and second subpixel electrodes 1210 and 2210 may be connected (e.g., electrically connected) to the connection metal CM through contact holes defined (or formed) in the second organic insulating layer 109.

A subpixel-defining layer 111 may be disposed on the second organic insulating layer 109. The subpixel-defining layer 111 may cover edge regions (or edges) of the first and second subpixel electrodes 1210 and 2210. For example, the subpixel-defining layer 111 may include a first opening 111-OP1 and a second opening 111-OP2 exposing central portions of the first and second subpixel electrodes 1210 and 2210, respectively. For example, the first opening 111-OP1 may expose the central portion of the first subpixel electrode 1210. The second opening 111-OP2 may expose the central portion of the second subpixel electrode 2210.

The subpixel-defining layer 111 may include a trench TR arranged between the first and second subpixel electrodes 1210 and 2210 in plan view. The trench TR may be in the shape of a blind hole that does not pass through the subpixel defining layer 111. An upper portion of the trench TR may be included in an air gap SPC as a gap.

The subpixel-defining layer 111 may include a tip portion T protruding from a side surface of the subpixel-defining layer 111 toward the air gap SPC. For example, the subpixel-defining layer 111 may include the tip portion T protruding from an inner side surface of the subpixel-defining layer 111 toward the air gap SPC.

The subpixel-defining layer 111 may include an organic insulating material. For example, the subpixel-defining layer 111 may include an inorganic insulating material such as silicon oxide (SiOₓ) or silicon nitride (SiNₓ).

An electrode layer HM may be disposed in the trench TR. In case that a voltage is applied to the electrode layer HM, the electrode layer HM may generate Joule heat to vaporize and/or sublimate the material disposed on the surface of the electrode layer HM, thereby removing the material.

A shape of the electrode layer HM may be similar to that of the trench TR. For example, both the electrode layer HM and the trench TR may have a substantially trapezoidal shape in which an upper surface is shorter than a lower surface. However, embodiments are not limited thereto, and the shapes of the electrode layer HM and the trench TR may be variously modified.

At least one of outer surfaces of the electrode layer HM facing each other may be spaced apart from at least one of inner surfaces of the trench TR facing each other. For example, a side surface of the electrode layer HM may be spaced apart from an inner side surface of the subpixel-defining layer 111 in which the trench TR is formed. Because an outer surface of the electrode layer HM and an inner surface of the trench TR are spaced apart from each other, a space in which a redistribution layer RE is to be disposed may be ensured.

The redistribution layer RE may be disposed in a portion of a space in the trench TR where the electrode layer HM is not disposed. The redistribution layer RE may include at least one of a hole injection layer HIL, first and second emitting units EU1 and EU2, and first and second charge generation layers CGL1 and CGL2, which will be described later.

The intermediate layer 220 may include a hole injection layer, emitting units, at least one charge generation layer, and an electron injection layer. For example, the intermediate layer 220 may include a hole injection layer HIL, first, second, and third emitting units EU1, EU2, and EU3, first and second charge generation layers CGL1 and CGL2, and an electron injection layer EIL.

The hole injection layer HIL may be disposed on the first and second subpixel electrodes 1210 and 2210. The hole injection layer HIL may cover respective portions of the first and second subpixel electrodes 1210 and 2210 and the subpixel-defining layer 111. A portion of the hole injection layer HIL may be disposed on the tip portion T of the subpixel-defining layer 111.

The hole injection layer HIL may be broken (or disconnected/separated) in a region overlapping the trench TR. For example, the hole injection layer HIL may be bent at the tip portion T of the subpixel-defining layer 111 to cover a portion of the tip portion T (e.g., a side surface of the tip portion T). For example, a portion of the hole injection layer HIL may be disposed within an upper portion of the trench TR.

Emitting units and at least one charge generation layer may be disposed on the hole injection layer HIL. The charge generation layer may be interposed between adjacent emitting units. For example, the first, second, and third emitting units EU1, EU2, and EU3 may be disposed on the hole injection layer HIL. The first charge generation layer CGL1 may be interposed between the first emitting unit EU1 and the second emitting unit EU2. The second charge generation layer CGL2 may be interposed between the second emitting unit EU2 and the third emitting unit EU3. The first and second charge generation layers CGL1 and CGL2 may include a conductive material.

The first emitting unit EU1 may be disposed on the hole injection layer HIL. The first emitting unit EU1 may cover the hole injection layer HIL. A portion of the first emitting unit EU1 may be disposed on the tip portion T of the subpixel-defining layer 111.

The first emitting unit EU1 may be broken (or disconnected/separated) in a region overlapping the trench TR. For example, the first emitting unit EU1 may be bent at the tip portion T of the subpixel-defining layer 111 to cover a portion of the tip portion T (e.g., a side surface of the tip portion T). For example, a portion of the first emitting unit EU1 may be disposed within the upper portion of the trench TR.

The first charge generation layer CGL1 may be disposed on the first emitting unit EUL. The first charge generation layer CGL1 may cover the first emitting unit EU1. A portion of the first charge generation layer CGL1 may be disposed on the tip portion T of the subpixel-defining layer 111.

The first charge generation layer CGL1 may be broken (or disconnected/separated) in a region overlapping the trench TR. For example, the first charge generation layer CGL1 may be bent at the tip portion T of the subpixel-defining layer 111 to cover a portion of the tip portion T (e.g., a side surface of the tip portion T). For example, a portion of the first charge generation layer CGL1 may be disposed within the upper portion of the trench TR. The first charge generation layer CGL1 may include a conductive material.

The second emitting unit EU2 may be disposed on the first charge generation layer CGL1. The second emitting unit EU2 may cover the first charge generation layer CGL1. A portion of the second emitting unit EU2 may be disposed on the tip portion T of the subpixel-defining layer 111.

The second emitting unit EU2 may be broken (or disconnected/separated) in a region overlapping the trench TR. For example, the second emitting unit EU2 may be bent at the tip portion T of the subpixel-defining layer 111 to cover a portion of the tip portion T (e.g., a side surface of the tip portion T). For example, a portion of the second emitting unit EU2 may be disposed within the upper portion of the trench TR.

The second charge generation layer CGL2 may be disposed on the second emitting unit EU2. The second charge generation layer CGL2 may cover the second emitting unit EU2. A portion of the second charge generation layer CGL2 may be disposed on the tip portion T of the subpixel-defining layer 111.

The second charge generation layer CGL2 may be broken (or disconnected/separated) in a region overlapping the trench TR. For example, the second charge generation layer CGL2 may be bent at the tip portion T of the subpixel-defining layer 111 to cover a portion of the tip portion T (e.g., a side surface of the tip portion T). For example, a portion of the second charge generation layer CGL2 may be disposed within the upper portion of the trench TR. The second charge generation layer CGL2 may include a conductive material.

The third emitting unit EU3 may be disposed on the second charge generation layer CGL2. The third emitting unit EU3 may cover a portion of the second charge generation layer CGL2. Unlike the first and second emitting units EU1 and EU2, the third emitting unit EU3 may be continuous (or continuously extend) in the region overlapping the trench TR. For example, the third emitting unit EU3 may not be broken (or disconnected/separated) in the air gap SPC.

A portion of the third emitting unit EU3 overlapping the air gap SPC may have a different thickness from the other portion. For example, a thickness of the third emitting unit EU3 may decrease from a point where a lower surface of the third emitting unit EU3 meets a side surface of a portion of the second charge generation layer CGL2 disposed above the trench TR toward the air gap SPC. For example, the third emitting unit EU3 may be concave in a thickness direction in a region overlapping the air gap SPC.

The electron injection layer EIL may be disposed on the third emitting unit EU3. The electron injection layer EIL may cover the third emitting unit EU3. The electron injection layer EIL may be connected in a region overlapping the trench TR. For example, the electron injection layer EIL may not be broken (or disconnected/separated) in the air gap SPC.

A portion of the electron injection layer EIL overlapping the air gap SPC may have a different thickness from the other portion. For example, because the portion of the electron injection layer EIL overlapping the air gap SPC is disposed on a concave portion of the third emitting unit EU3, the portion of the electron injection layer EIL may be thicker than the other portion of the electron injection layer EIL. For example, the electron injection layer EIL may be convex in a negative z-axis direction in a region overlapping the air gap SPC.

An opposite electrode 230 may be disposed on the electron injection layer EIL. The opposite electrode 230 may include a metal, an alloy, a conductive compound each having a low work function, or an arbitrary combination thereof. For example, the opposite electrode 230 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The opposite electrode 230 may be a transmissive electrode, a semi-transmissive electrode, or a reflective electrode.

A capping layer CPL may be positioned on the opposite electrode 230. The capping layer CPL may have a lower refractive index than the opposite electrode 230, and may improve luminescent efficiency by decreasing a percentage that light generated by the intermediate layer 220 is totally reflected and thus is not emitted to the outside.

For example, the capping layer CPL may include an organic material, such as poly(3,4-ethylenedioxythiophene) (or PEDOT), 4,4′-bis [N-(3-methylphenyl)-N-phenylamino] biphenyl (TPD), 4,4′,4″-tris [(3-methylphenyl) phenylamino] triphenylamine (m-MTDATA), 1,3,5-tris [N,N-bis(2-methylphenyl)-amino]-benzene (o-MTDAB), 1,3,5-tris [N, N-bis (3-methylphenyl)-amino]-benzene (m-MTDAT), 1,3,5-tris [N,N-bis (4-methylphenyl)-amino]-benzene (p-MTDAB), 4,4′-bis [N, N-bis (3-methylphenyl)-amino]-diphenylmethane (BPPM), 4,4′-dicarbazolyl-1,1′-biphenyl (CBP), 4,4′,4″-tris (N-carbazole) triphenylamine (TCTA), 2,2′,2″-(1,3,5-benzenetolyl) tris-[1-phenyl-1H-benzoimidazole] (TPBI), and 3-(4-biphenyl)-4-phenyl-5-t-butylphenyl-1,2,4-triazole (TAZ).

In another example, the capping layer CPL may include an inorganic material such as zinc oxide (ZnO), titanium oxide (TiO₂), zirconium oxide (ZrO₂), nitrogen oxide (NO), niobium oxide (NbOₓ), tantalum oxide (TaOₓ), tin oxide (SnO₂), nickel oxide (NiOₓ), indium nitride (InN), and gallium nitride (GaN). The materials used to form the capping layer CPL are not limited thereto, and various other materials may be used.

An encapsulation layer 300 may be disposed on the capping layer CPL. The encapsulation layer 300 may include at least one inorganic encapsulation layer and at least one organic encapsulation layer. For example, the encapsulation layer 300 may include a first inorganic encapsulation layer 310, a second inorganic encapsulation layer 330, and an organic encapsulation layer 320 interposed between the first and second inorganic encapsulation layers 310 and 330. The first and second inorganic encapsulation layers 310 and 330 may include an inorganic insulating material such as silicon oxide (SiOₓ), silicon nitride (SiNₓ), or silicon oxynitride (SiOₓN_{y}), and the organic encapsulation layer 320 may include at least one organic insulating material selected from polyethylene terephthalate (PET), polyethylenenaphthalate (PEN), polycarbonate (PC), polyamide (PI), polyethylenesulfonate (PES), polyoxymethylene (POM), polyarylate (PAR), and hexamethyldisiloxane (HMDSO).

First and second color filters CF1 and CF2 may be disposed on the encapsulation layer 300. First and second color filters CF1 and CF2 may be disposed to correspond to the first and second subpixel electrodes 1210 and 2210, respectively. For example, the first color filter CF1 may overlap the first subpixel electrode 1210. The second color filter CF2 may overlap the second subpixel electrode 2210. The first and second color filters CF1 and CF2 may transmit only light of a certain color. For example, the first color filter CF1 may transmit red light and the second color filter CF2 may transmit green light. According to an embodiment, only red light among light emitted by a portion of the intermediate layer 220 overlapping the first subpixel electrode 1210 may pass through the first color filter CF1 and thus may be emitted. Only green light among light emitted by a portion of the intermediate layer 220 overlapping the second subpixel electrode 2210 may pass through the second color filter CF2 and thus may be emitted.

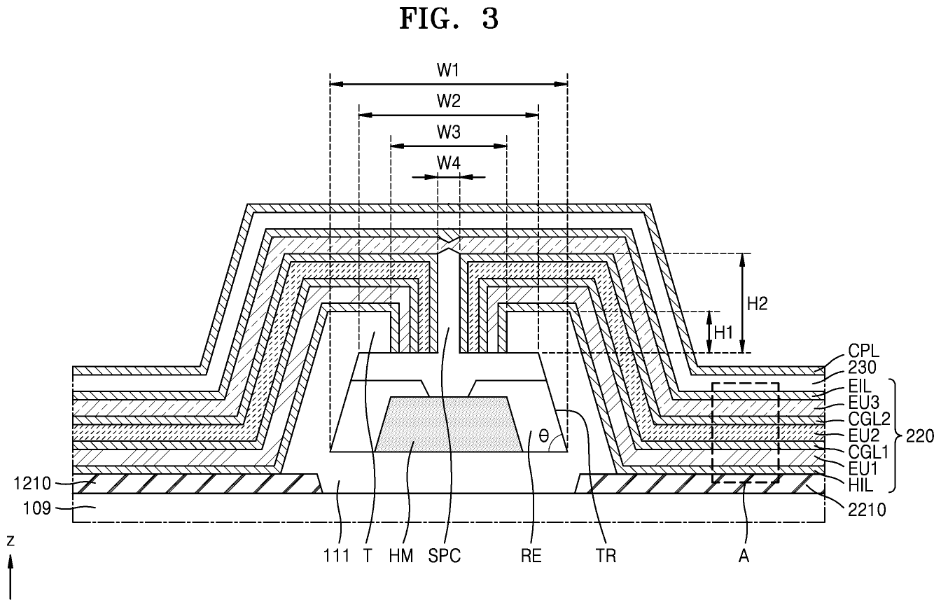

FIG. 3 is a magnified schematic cross-sectional view of a portion of the display apparatus 1 according to an embodiment.

Referring to FIG. 3, the subpixel-defining layer 111 may include the trench TR.

The subpixel-defining layer 111 may include side surfaces forward tapered with respect to respective upper surfaces of the first and second subpixel electrodes 1210 and 2210.

In the following description, forward tapering may mean that an angle formed between a surface and another surface is an obtuse angle. For example, a side surface of the subpixel-defining layer 111 being forward tapered with respect to the upper surface of the first subpixel electrode 1210 may be a side surface of the subpixel-defining layer 111 forming an obtuse angle with the upper surface of the first subpixel electrode 1210.

In the following description, backward tapering may mean that an angle formed between a surface and another surface is an acute angle. For example, a side surface of the subpixel-defining layer 111 being backward tapered with respect to the upper surface of the first subpixel electrode 1210 may be a side surface of the subpixel-defining layer 111 forming an acute angle with the upper surface of the first subpixel electrode 1210.

Although FIG. 3 shows that the side surfaces of the subpixel-defining layer 111 includes side surfaces tapered in a forward direction with respect to the first subpixel electrode 1210 and the second subpixel electrode 2210, embodiments are not limited thereto. In another example, the subpixel-defining layer 111 may include side surfaces backward tapered with respect to the first and/or second subpixel electrodes 1210 and/or 2210 or vertical side surfaces.

The subpixel-defining layer 111 may include a tip portion T protruding toward the trench TR. For example, the subpixel-defining layer 111 may include a tip portion T protruding, toward the air gap SPC, from an inner side surface of the subpixel-defining layer 111 on which the trench TR is disposed.

According to an embodiment, portions of end portions (e.g., opposite end portions) of the subpixel-defining layer 111 disposed between the first subpixel electrode 1210 and the second subpixel electrode 2210 may extend obliquely in a positive z-axis direction with constant thicknesses, and then may be bent in positive and negative x-axis directions to be flattened. A portion bent in the positive and negative x-axis directions and protruding from the obliquely extending portions may be the tip portion T. FIG. 3 shows that the subpixel-defining layer 111 and the tip portion T have constant thicknesses, but embodiments are not limited thereto. In another example, the subpixel-defining layer 111 and the tip portion T may have inconstant thicknesses.

A distance W3 between tip portions T may be smaller than a width W2 of an upper end portion of the trench TR. For example, the subpixel-defining layer 111 may have an undercut structure. FIG. 3 shows that the distance W3 between tip portions T is constant, but embodiments are not limited thereto. In another example, the distance W3 between tip portions T may decrease in a direction (e.g., the positive and negative z-axis directions).

The trench TR may have a shape in which a width decreases in a direction. For example, the width of the trench TR may decrease in the positive z-axis direction. According to an embodiment, the trench TR may have a substantially trapezoidal shape in which a width W1 of a lower end portion is greater than a width W2 of an upper end portion. In another example, the trench TR may have a substantially dome shape in which the width W1 of the lower end portion is greater than the width W2 of the upper end portion.

Although FIG. 3 shows that the width W1 of the lower end portion of the trench TR is greater than the width W2 of the upper end portion of the trench TR, embodiments are not limited thereto. In another example, the width of the trench TR may decrease in the negative z-axis direction. For example, the trench TR may have a substantially trapezoidal shape in which the width W1 of the lower end portion is less than the width W2 of the upper end portion. In another example, the width of the trench TR may be constant in the positive and negative z-axis directions. For example, the trench TR may have a substantially rectangular shape in which the width W1 of the lower end portion is substantially equal to the width W2 of the upper end portion.

An angle θ formed between a side surface and a lower surface of the trench TR may be modified according to the shape of the trench TR. For example, in case that the width W1 of the lower end portion of the trench TR is greater than the width W2 of the upper end portion of the trench TR, an angle θ between the side surface and the lower surface of the trench TR may be an acute angle. In case that the width W1 of the lower end portion of the trench TR is less than the width W2 of the upper end portion of the trench TR, the angle θ between the side surface and the lower surface of the trench TR may be an obtuse angle. In case that the width W1 of the lower end portion of the trench TR is substantially equal to the width W2 of the upper end portion of the trench TR, the angle θ between the side surface and the lower surface of the trench TR may be a right angle. Embodiments are not limited thereto.

In another example, the trench TR may have a substantially hexagonal or octagonal shape in which the width W1 of the lower end portion of the trench TR is substantially equal to the width W2 of the upper end portion of the trench TR and the angle θ between the side surface and the lower surface of the trench TR is an obtuse angle. The trench TR may have a substantially hourglass shape in which the width W1 of the lower end portion of the trench TR is substantially equal to the width W2 of the upper end portion of the trench TR and the angle θ between the side surface and the lower surface of the trench TR is an acute angle. As such, the shape of the trench TR may be variously changed, and there is no separate limitation on the shape itself.

A portion of the upper portion of the trench TR may be included in the air gap SPC. According to an embodiment, a space between the tip portions T of the subpixel-defining layer 111 may be defined as the upper portion of the trench TR. For example, a portion of the upper portion of the trench TR may be filled with the hole injection layer HIL, the first and second emitting units EU1 and EU2, and the first and second charge generation layers CGL1 and CGL2, and the remaining unfilled portion may be included in the air gap SPC.

The intermediate layer 220 may be disposed on the first and second subpixel electrodes 1210 and 2210 and the subpixel-defining layer 111. The hole injection layer HIL, the first emitting unit EU1, the first charge generation layer CGL1, the second emitting unit EU2, and the second charge generation layer CGL2 in the intermediate layers 220 may be broken (or disconnected/separated) in a region overlapping the trench TR. For example, the hole injection layer HIL, the first emitting unit EU1, the first charge generation layer CGL1, the second emitting unit EU2, and the second charge generation layer CGL2 may be broken (or disconnected/separated) in the air gap SPC and thus may define the air gap SPC.

Respective portions of the hole injection layer HIL, the first emitting unit EU1, the first charge generation layer CGL1, the second emitting unit EU2, and the second charge generation layer CGL2 may be disposed on the upper surface and side surfaces of the tip portion T of the subpixel-defining layer 111.

As the hole injection layer HIL, the first emitting unit EU1, the first charge generation layer CGL1, the second emitting unit EU2, and the second charge generation layer CGL2 are stacked, the width of the air gap SPC may decrease. For example, the distance W3 between the tip portions T, which is the width of the air gap SPC, before the hole injection layer HIL is disposed may be greater than the width W4 of the air gap SPC after the second charge generation layer CGL2 is disposed.

As the hole injection layer HIL, the first emitting unit EU1, the first charge generation layer CGL1, the second emitting unit EU2, and the second charge generation layer CGL2 are stacked, the air gap SPC may extend in the positive z-axis direction. For example, a height H1 of the air gap SPC before the hole injection layer HIL may be disposed may be less than a height H2 of the air gap SPC after the second charge generation layer CGL2 is disposed.

Accordingly, the air gap SPC may include a space extending in the positive z-axis direction between stacks of the hole injection layer HIL, the first emitting unit EU1, the first charge generation layer CGL1, the second emitting unit EU2, and the second charge generation layer CGL2 and a portion of the upper portion of the trench TR.

The third emitting unit EU3, the electron injection layer EIL, the opposite electrode 230, and the capping layer CPL may be disposed on the second charge generation layer CGL2. The third emitting unit EU3, the electron injection layer EIL, the opposite electrode 230, and the capping layer CPL may be connected in regions overlapping the trench TR.

The electrode layer HM may be disposed in the trench TR. The electrode layer HM may be spaced apart from the inner side surfaces of the subpixel-defining layer 111. The shape of the electrode layer HM may be similar to or smaller than that of the trench TR. For example, like the trench TR, the electrode layer HM may have a substantially trapezoidal shape in which an upper surface is wider than a lower surface. However, embodiments are not limited thereto, and the shape of the electrode layer HM may be variously modified.

The electrode layer HM may include a metal, alloy, or any combination that does not have a low specific resistance and a low melting point. For example, the electrode layer HM may include molybdenum (Mo), titanium (Ti), a molybdenum (Mo) alloy, or a titanium (Ti) alloy. The electrode layer HM may include a transparent layer. For example, the electrode layer HM may include a transparent layer including indium tin oxide (ITO), indium zinc oxide (IZO), zinc oxide (ZnO), indium oxide (In₂O₃), indium gallium oxide (IGO), or aluminum zinc oxide (AlZO). For example, embodiments are not limited thereto, and the electrode layer HM may include any of various other materials and may have any of various structures, such as, a single-layered structure or a multi-layered structure.

The redistribution layer RE may be disposed between the electrode layer HM and the inner side surfaces of the subpixel-defining layer 111. The redistribution layer RE may be a structure in which respective portions of the hole injection layer HIL, the first emitting unit EU1, the first charge generation layer CGL1, the second emitting unit EU2, and the second charge generation layer CGL2 broken (or disconnected/separated) in the air gap SPC are stacked. In another example, the redistribution layer RE may include compounds of at least two of the hole injection layer HIL, the first emitting unit EU1, the first charge generation layer CGL1, the second emitting unit EU2, and the second charge generation layer CGL2.

The redistribution layer RE may expose a portion of the upper surface of the electrode layer HM.

Although the hole injection layer HIL, the first emitting unit EU1, the first charge generation layer CGL1, the second emitting unit EU2, and the second charge generation layer CGL2 disposed on the upper surface of the redistribution layer RE and the tip portion T are illustrated as being spaced apart from one another in FIG. 3, embodiments are not limited thereto. In another example, the hole injection layer HIL, the first emitting unit EU1, the first charge generation layer CGL1, the second emitting unit EU2, and/or the second charge generation layer CGL2 disposed on the upper surface of the redistribution layer RE and the tip portion T may contact one another.

Because the redistribution layer RE may include the first and second charge generation layers CGL1 and CGL2, the redistribution layer RE may include a conductive material. However, because the redistribution layer RE may include the hole injection layer HIL and the first and second emitting units EU1 and EU2, the redistribution layer RE may not be conductive as a whole. Therefore, in case that the upper surface of the redistribution layer RE is in contact with (e.g., in direct contact with) the first and second charge generation layers CGL1 and CGL2, current may not flow through the first and second charge generation layers CGL1 and CGL2, the redistribution layer RE, and the electrode layer HM.

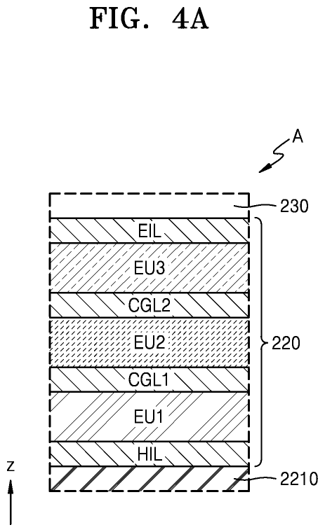

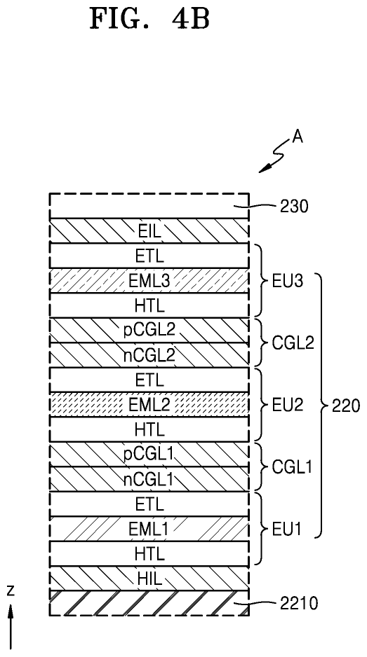

FIG. 4A is a magnified schematic cross-sectional view of region A of FIG. 3.

Referring to FIG. 4A, the intermediate layer 220 may be disposed between the second subpixel electrode 2210 and the opposite electrode 230. The characteristics of the second subpixel electrode 2210 and the opposite electrode 230 are the same as those previously described with reference to FIG. 2. The intermediate layer 220 may include a low molecular or high molecular organic material that emits light of a certain color. In addition to various organic materials, the intermediate layer 220 may further include a metal-containing compound such as an organic metal compound, an inorganic material such as quantum dots, and the like.

The intermediate layer 220 may include the hole injection layer HIL, the first, second, and third emitting units EU1, EU2, and EU3, the first and second charge generation layers CGL1 and CGL2, and the electron injection layer EIL.

In case that the intermediate layer 220 includes an emitting unit and a charge generation layer, a light-emitting diode (LED) may be a tandem LED. The LED may improve color purity and luminous efficiency by having a stacked structure of emitting units.

According to an embodiment, the hole injection layer HIL may be disposed between the second subpixel electrode 2210 and the first emitting unit EU1. The electron injection layer EIL may be disposed between the opposite electrode 230 and the third emitting unit EU3. The first, second, and third emitting units EU1, EU2, and EU3 may be disposed between the hole injection layer HIL and the electron injection layer EIL. A charge generation layer may be interposed between adjacent emitting units. For example, the first charge generation layer CGL1 may be interposed between the first emitting unit EU1 and the second emitting unit EU2. The second charge generation layer CGL2 may be interposed between the second emitting unit EU2 and the third emitting unit EU3.

FIG. 4B is a schematic cross-sectional view of the LED of FIG. 4A.

Referring to FIG. 4B, the first, second, and third emitting units EU1, EU2, and EU3 may include first, second, and third emission layers EML1, EML2, and EML3, respectively. For example, the first emitting unit EU1 may include the first emission layer EML1. The second emitting unit EU2 may include the second emission layer EML2. The third emitting unit EU3 may include the third emission layer EML3. Voltage may be applied to the first, second, and third emission layers EML1, EML2, and EML3 so that the first, second, and third emission layers EML1, EML2, and EML3 may emit light beams of different colors. For example, the first emission layer EML1 may emit blue light. The second emission layer EML2 may emit red light. The third emission layer EML3 may emit green light.

The first, second, and third emitting units EU1, EU2, and EU3 may include hole transport layers HTL, respectively, and electron transport layers ETL, respectively. According to an embodiment, the first, second, and third emission layers EML1, EML2, and EML3 may be interposed between their corresponding hole transport layers HTL and their corresponding electron transport layers ETL. For example, the first emitting unit EU1 may include the hole transport layer HTL, the first emission layer EML1 disposed on the hole transport layer HTL, and the electron transport layer ETL disposed on the first emission layer EML1. The second emitting unit EU2 may include the hole transport layer HTL, the second emission layer EML2 disposed on the hole transport layer HTL, and the electron transport layer ETL disposed on the second emission layer EML2. The third emitting unit EU3 may include the hole transport layer HTL, the third emission layer EML3 disposed on the hole transport layer HTL, and the electron transport layer ETL disposed on the third emission layer EML3.

The charge generation layer may include a negative charge generation layer and a positive charge generation layer. A tandem light-emitting device having emission layers may further increase emission efficiency of an LED due to a negative charge generation layer and a positive charge generation layer.

According to an embodiment, the first charge generation layer CGL1 may include a first negative charge generation layer nCGL1 and a first positive charge generation layer pCGL1 disposed on the first negative charge generation layer nCGL1. The second charge generation layer CGL2 may include a second negative charge generation layer nCGL2 and a second positive charge generation layer pCGL2 disposed on the second negative charge generation layer nCGL2.

The first and second negative charge generation layers nCGL1 and nCGL2 may be n-type charge generation layers. The first and second negative charge generation layers nCGL1 and nCGL2 may supply electrons. The first and second negative charge generation layers nCGL1 and nCGL2 may include a host and a dopant. The host may include an organic material. The dopant may include a metal material. The first and second positive charge generation layers pCGL1 and pCGL2 may be p-type charge generation layers. The first and second positive charge generation layers pCGL1 and pCGL2 may supply holes. The first and second positive charge generation layers pCGL1 and pCGL2 may include a host and a dopant. The host may include an organic material. The dopant may include a metal material.

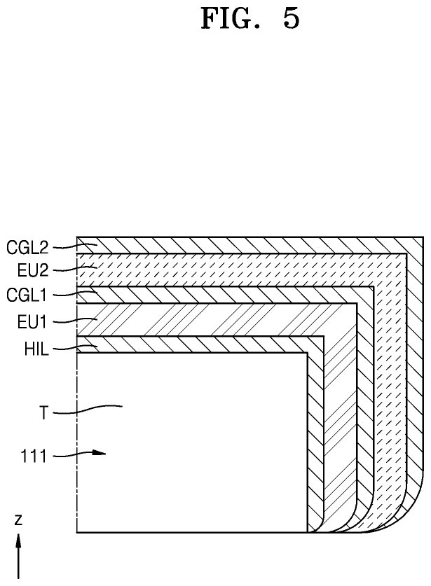

FIG. 5 is a magnified schematic cross-sectional view of a portion of the display apparatus 1 according to an embodiment.

Referring to FIG. 5, the hole injection layer HIL, the first and second emitting units EU1 and EU2, and the first and second charge generation layers CGL1 and CGL2 may be disposed on the upper surface and the side surface of the tip portion T of the subpixel-defining layer 111. FIG. 3 shows that the end portions (e.g., opposite end portions) of portions of the hole injection layer HIL, the first and second emitting units EU1 and EU2, and the first and second charge generation layers CGL1 and CGL2 disposed on the side surfaces of the tip portion T include right-angled corner portions, but embodiments are not limited thereto.

In another example, an end portion of the hole injection layer HIL disposed on the side surface of the tip portion T may include a rounded corner portion. An end portion of the first emitting unit EU1 disposed on the side surface of the tip portion T may include a rounded corner portion and may cover the corner portion of the hole injection layer HIL. An end portion of the first charge generation layer CGL1 disposed on the side surface of the tip portion T may include a rounded corner portion and may cover the corner portion of the first emitting unit EUL. An end portion of the second emitting unit EU2 disposed on the side surface of the tip portion T may include a rounded corner portion and may cover the corner portion of the first charge generation layer CGL1. An end portion of the second charge generation layer CGL2 disposed on the side surface of the tip portion T may include a rounded corner portion and may cover the corner portion of the second emitting unit EU2.

A width, in a direction, of a portion of each layer disposed at a corner portion may gradually decrease at its end portion. For example, a width of the hole injection layer HIL in the positive and negative x-axis directions may gradually decrease at the corner portion of its end portion. A width of the first emitting unit EU1 in the positive and negative x-axis directions may gradually decrease at the corner portion of its end portion. A width of the first charge generation layer CGL1 in the positive and negative x-axis directions may gradually decrease at the corner portion of its end portion. A width of the second emitting unit EU2 in the positive and negative x-axis directions may gradually decrease at the corner portion of its end portion. A width of the second charge generation layer CGL2 in the positive and negative x-axis directions may gradually decrease at the corner portion of its end portion.

Accordingly, unlike what is shown in FIG. 3, respective end portions (e.g., opposite end portions) of the hole injection layer HIL, the first emitting unit EU1, the first charge generation layer CGL1, and/or the second emitting unit EU2 may not be exposed but may be covered by the end portion of the second charge generation layer CGL2.

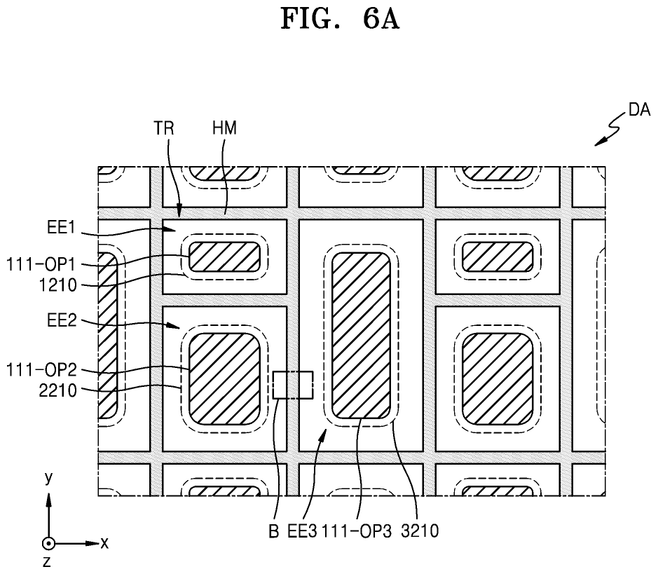

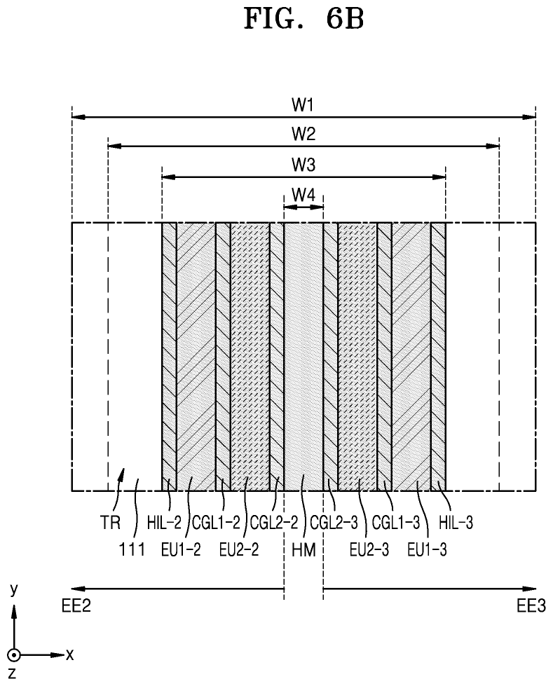

FIG. 6A is a magnified schematic plan view of a portion of the display area of the display apparatus 1 according to an embodiment.

Referring to FIG. 6A, emission elements may be two-dimensionally arranged in the x-axis direction and the y-axis direction in the display area DA. An array of emission elements, for example, an array of first emission elements EE1, second emission elements EE2, and third emission elements EE3, may define a display area.

According to an embodiment, the array of emission elements may include columns arranged in the y-axis direction. Two emission elements among different emission elements, for example, a first emission element EE1 and a second emission element EE2, may be arranged in the same column, and a remaining emission element, for example, a third emission element EE3, may be arranged in a different column. First emission elements EE1 and second emission elements EE2 corresponding to an i-th column may be alternately arranged, and may be spaced apart from each other in the y-axis direction, where i is a natural number. Third emission elements EE3 corresponding to an (i+1)-th column may be spaced apart from each other. The array of emission elements may have a structure in which the above-described i-th column and the above-described (i+1)-th column are repeated in the x-axis direction.

According to an embodiment, a distance between a first emission element EE1 and a second emission element EE2 adjacent to each other in the same column (e.g., the i-th column) may be substantially the same as another distance between another first emission element EE1 and another second emission element EE2 adjacent to each other. A distance between a pair of third emission elements EE3 adjacent to each other in the same column (e.g., the (i+1)-th column) may be substantially the same as another distance between another pair of third emission elements EE3 adjacent to each other.

A first emission element EE1, a second emission element EE2, and a third emission element EE3 may have different areas. For example, the area (or size) of the third emission element EE3 may be greater than that of the second emission element EE2, and the area (or size) of the second emission element EE2 may be greater than that of the first emission element EEL. According to an embodiment, the area (or size) of the third emission element EE3 may be substantially equal to a sum of the area (or size) of the first emission element EE1 and the area (or size) of the second emission element EE2.

The first, second, and third emission elements EE1, EE2, and EE3 may include first, second, and third subpixel electrodes 1210, 2210, and 3210, respectively. For example, the first emission element EE1 may include the first subpixel electrode 1210. The second emission element EE2 may include the second subpixel electrode 2210. The third emission element EE3 may include the third subpixel electrode 3210.

The first, second, and third subpixel electrodes 1210, 2210, and 3210 may overlap first, second, and third openings 111-OP1, 111-OP2, and 111-OP3 of the subpixel-defining layer 111, respectively. For example, the first subpixel electrode 1210 may overlap the first opening 111-OP1. The second subpixel electrode 2210 may overlap the second opening 111-OP2. The third subpixel electrode 3210 may overlap the third opening 111-OP3.

Respective areas (or sizes) of the first, second, and third subpixel electrodes 1210, 2210, and 3210 may be greater than those of the first, second, and third openings 111-OP1, 111-OP2, and 111-OP3, respectively. For example, the area (or size) of the first subpixel electrode 1210 may be greater than that of the first opening 111-OP1. The area (or size) of the second subpixel electrode 2210 may be greater than that of the second opening 111-OP2. The area (or size) of the third subpixel electrode 3210 may be greater than that of the third opening 111-OP3. The first, second, and third openings 111-OP1, 111-OP2, and 111-OP3 may expose respective central portions of the first, second, and third subpixel electrodes 1210, 2210, and 3210, respectively.

Although FIG. 6A shows that the first, second, and third subpixel electrodes 1210, 2210, and 3210 and the first, second, and third openings 111-OP1, 111-OP2, and 111-OP3 have rectangular shapes with rounded corner portions, embodiments are not limited thereto. The shapes of the first, second, and third subpixel electrodes 1210, 2210, and 3210 and/or the first, second, and third openings 111-OP1, 111-OP2, and 111-OP3 may be changed to various other shapes such as a polygon (e.g., N-gon, where N is a natural number substantially equal to or greater than 3) and an ellipse.

The trench TR may be disposed between the first, second, and third emission elements EE1, EE2, and EE3 adjacent to one another. For example, a portion of the trench TR may be disposed in a space between the first emission element EE1 and the second emission element EE2. A portion of the trench TR may be disposed in a space between the second emission element EE2 and the third emission element EE3. A portion of the trench TR may be disposed in a space between the first emission element EE1 and the third emission element EE3. The trench TR may extend in the positive and negative x-axis directions and the positive and negative y-axis directions.

The trench TR may have a shape surrounding the first, second, and third emission elements EE1, EE2, and EE3. For example, the trench TR may have a mesh shape or a net shape, and the first, second, and third emission elements EE1, EE2, and EE3 may be disposed in a space defined through the trench TR.

The electrode layer HM may overlap the trench TR. For example, the electrode layer HM may be disposed in the trench TR. The electrode layer HM may extend in the positive and negative x-axis directions and the positive and negative y-axis directions. The electrode layer HM may have a shape surrounding the first, second, and third emission elements EE1, EE2, and EE3. For example, the electrode layer HM may have a mesh shape or a net shape, and the first, second, and third emission elements EE1, EE2, and EE3 may be disposed in a space defined through the electrode layer HM and the trench TR.

Although FIG. 6A shows that the trench TR and the electrode layer HM are formed of straight lines and have angled corner portions, embodiments are not limited thereto. In another example, the trench TR and/or the electrode layer HM may include straight lines and/or curves, and may have rounded corner portions.

FIG. 6B is a magnified schematic plan view of region B of FIG. 6A.

Referring to FIG. 6A, an emission element may be disposed on the subpixel-defining layer 111 and may include a plurality of layers. For example, the second emission element EE2 may include a second hole injection layer HIL-2, a 1-2^{nd} emitting unit EU1-2, a 1-2^{nd} charge generation layer CGL1-2, a 2-2^{nd} emitting unit EU2-2, and a 2-2^{nd} charge generation layer CGL2-2. The third emission element EE3 may include a third hole injection layer HIL-3, a 1-3^{rd} emitting unit EU1-3, a 1-3^{rd} charge generation layer CGL1-3, a 2-3^{rd} emitting unit EU2-3, and a 2-3^{rd} charge generation layer CGL2-3.

At least one of a plurality of layers of the second and third emission elements EE2 and EE3 may overlap the electrode layer HM. For example, at least one of the second hole injection layer HIL-2, the 1-2^{nd} emitting unit EU1-2, the 1-2^{nd} charge generation layer CGL1-2, the 2-2^{nd} emitting unit EU2-2, and the 2-2^{nd} charge generation layer CGL2-2 of the second emission element EE2 may overlap the electrode layer HM. At least one of the third hole injection layer HIL-3, the 1-3^{rd} emitting unit EU1-3, the 1-3^{rd} charge generation layer CGL1-3, the 2-3^{rd} emitting unit EU2-3, and the 2-3^{rd} charge generation layer CGL2-3 of the third emission element EE3 may overlap the electrode layer HM.

The electrode layer HM may be disposed in the negative z-axis direction than the second and third emission elements EE2 and EE3. For example, the second and third emission elements EE2 and EE3 may be disposed on the electrode layer HM to overlap a portion of the electrode layer HM.

The trench TR may be formed to partially overlap the second and third emission elements EE2 and EE3 in the negative z-axis direction than the second and third emission elements EE2 and EE3. The width W2 of the upper end portion of the trench TR may be greater than a width W3 of the electrode layer HM.

At least one of the plurality of layers of the second and third emission elements EE2 and EE3 may expose the electrode layer HM. For example, the 2-2^{nd} charge generation layer CGL2-2 and the 2-3^{rd} charge generation layer CGL2-3 may be spaced apart from each other to expose a portion of the electrode layer HM.

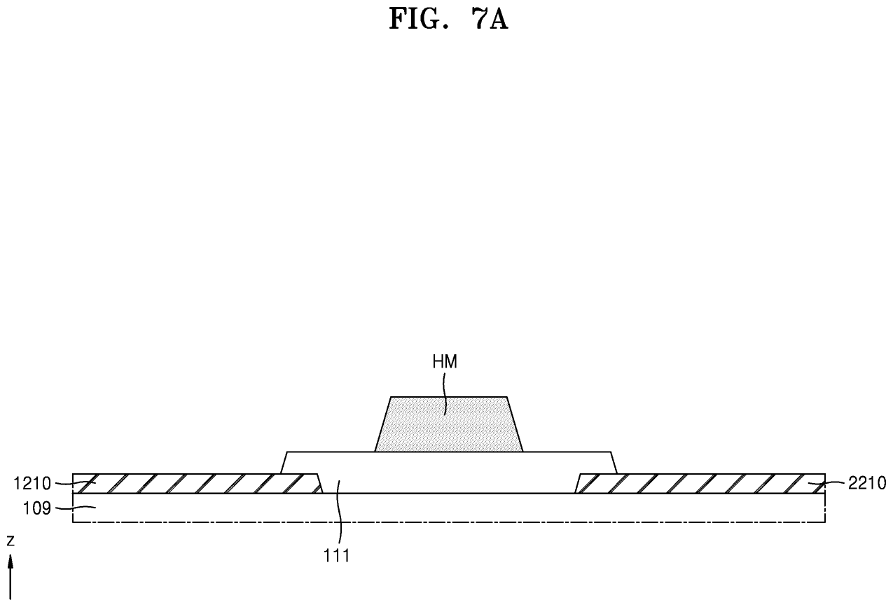

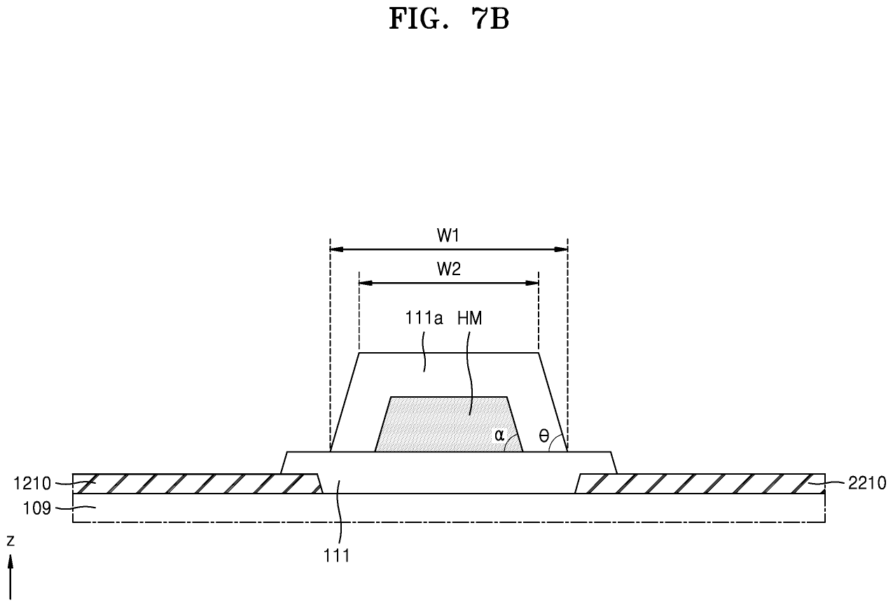

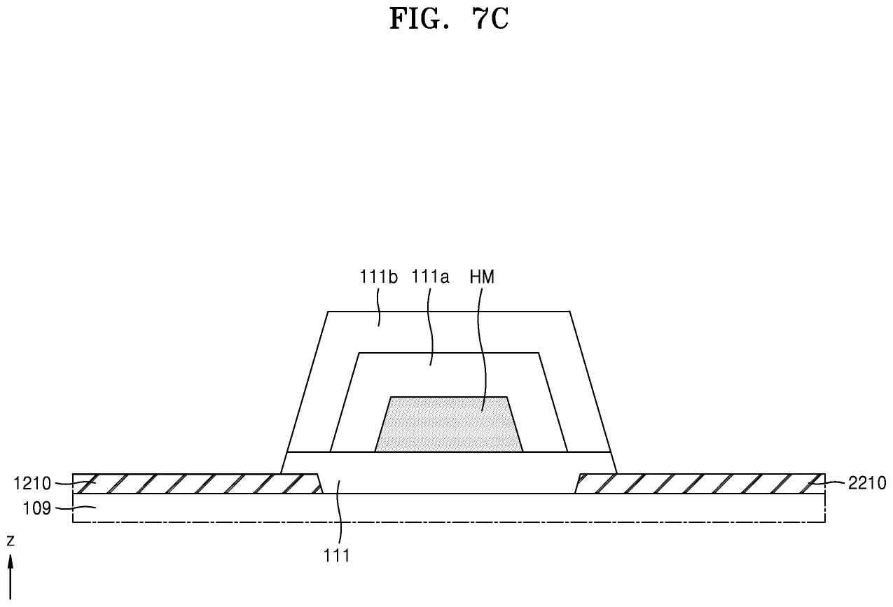

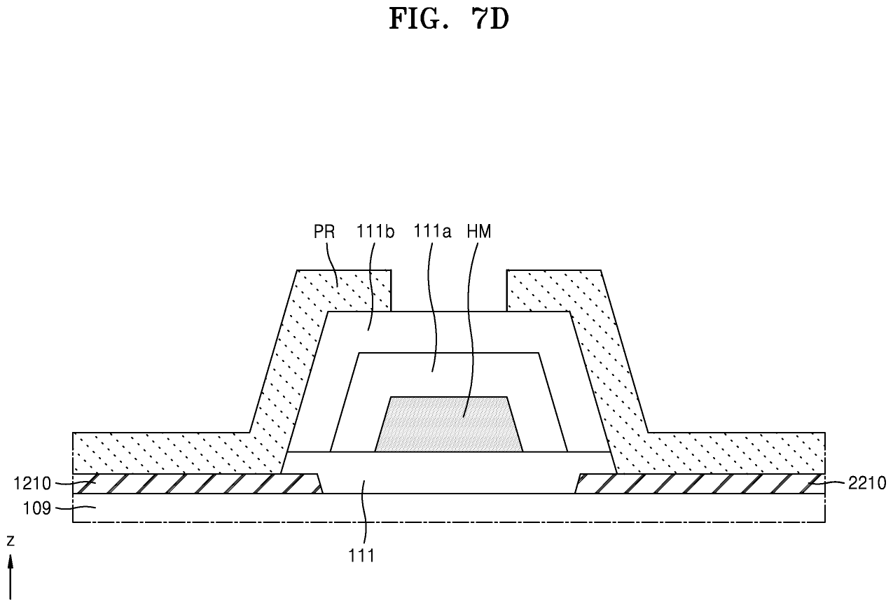

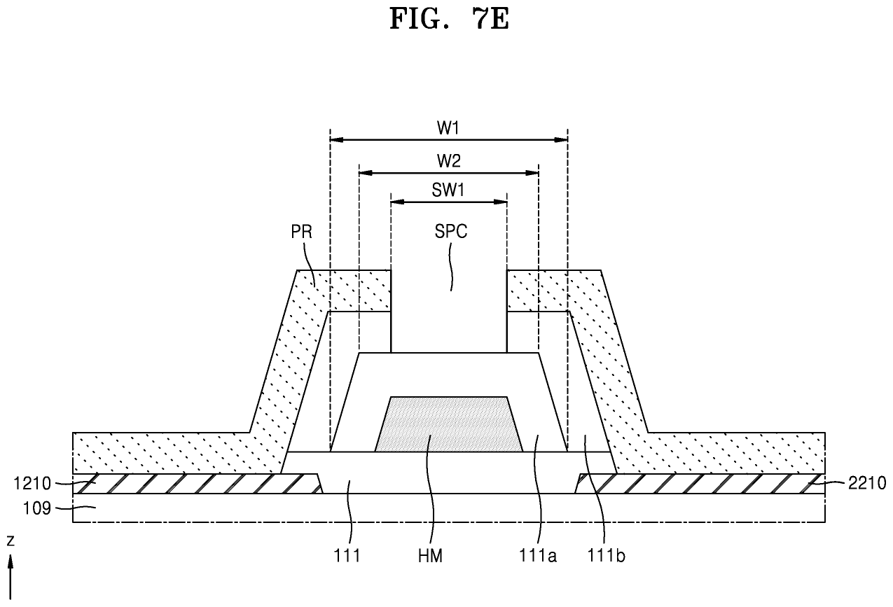

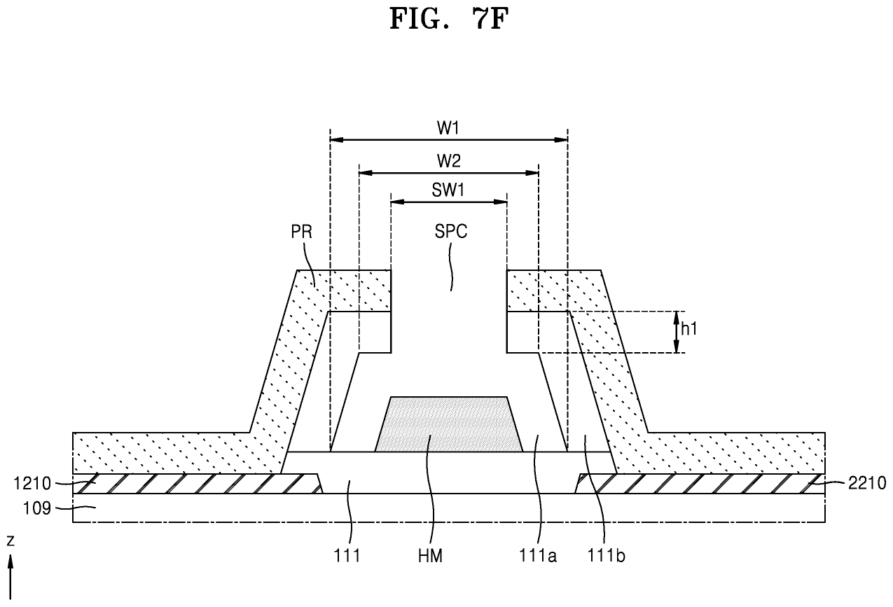

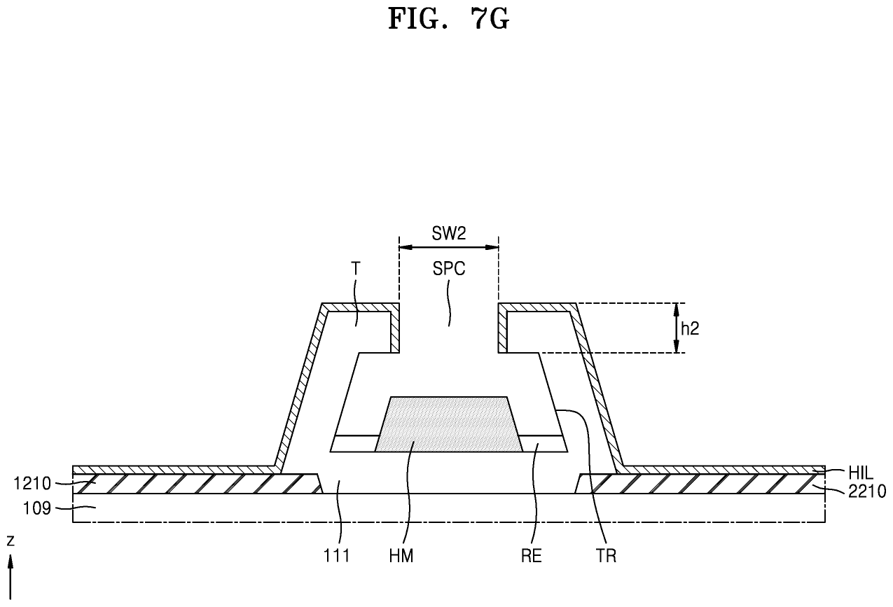

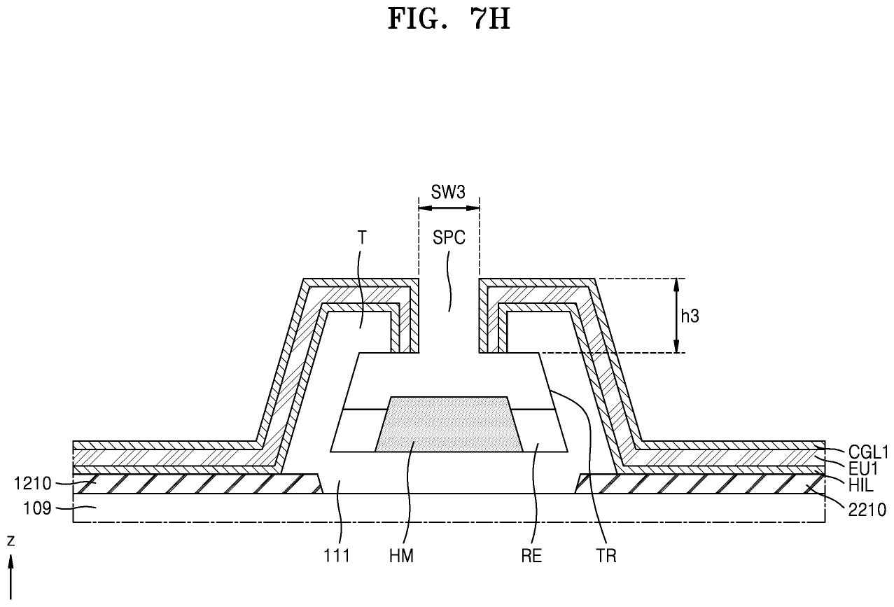

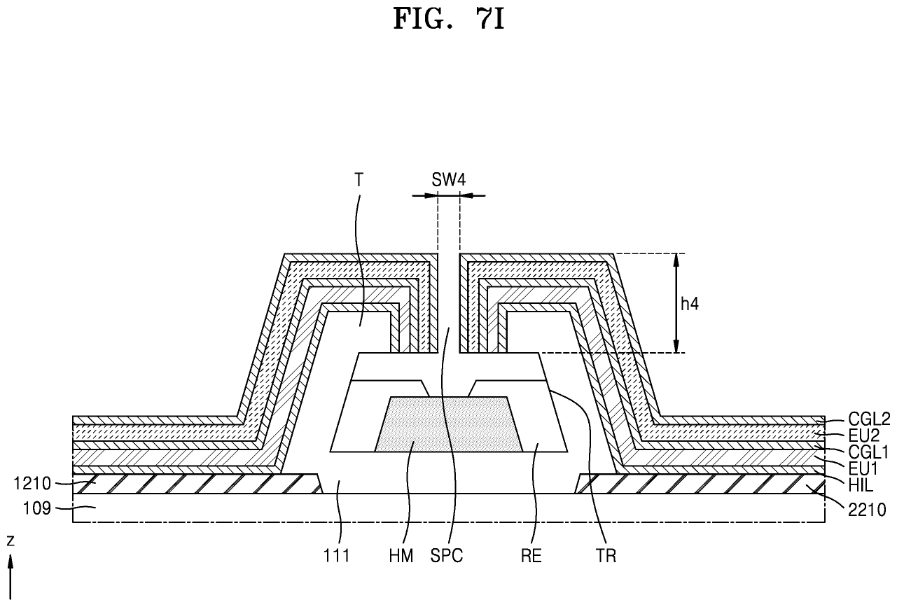

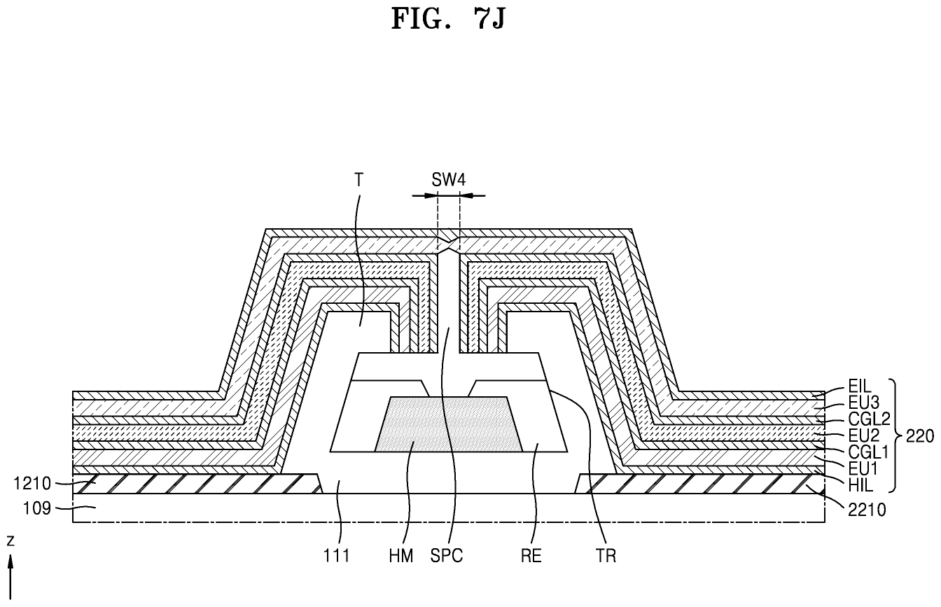

FIGS. 7A, 7B, 7C, 7D, 7E, 7F, 7G, 7H, 7I, and 7J are schematic cross-sectional views illustrating a manufacturing method according to an embodiment.

Referring to FIG. 7A, the first and second subpixel electrodes 1210 and 2210 may be disposed to be spaced apart from each other on the second organic insulating layer 109. The subpixel-defining layer 111 may be disposed between the first and second subpixel electrodes 1210 and 2210. The subpixel-defining layer 111 may cover edge regions (or edges) of the first and second subpixel electrodes 1210 and 2210. The side surfaces of the subpixel-defining layer 111 may be forward tapered with respect to the respective upper surfaces of the first and second subpixel electrodes 1210 and 2210.

The electrode layer HM may be disposed on the subpixel-defining layer 111. The side surfaces of the electrode layer HM may be forward tapered with respect to the upper surface of the subpixel-defining layer 111.

Referring to FIG. 7B, a first inorganic layer 111a may be formed on the electrode layer HM. The first inorganic layer 111a may cover the electrode layer HM. Similar to the electrode layer HM, a width W2 of an upper surface of the first inorganic layer 111a may be less than a width W1 of a lower surface of the first inorganic layer 111a. An angle α formed between a side surface of the electrode layer HM and the upper surface of the subpixel-defining layer 111 may be substantially the same as an angle θ formed between the side surface of the first inorganic layer 111a and the upper surface of the subpixel-defining layer 111. For example, the first inorganic layer 111a may be forward tapered with respect to the upper surface of the subpixel-defining layer 111. The first inorganic layer 111a may be in contact with (e.g., in direct contact with) the subpixel-defining layer 111.

The first inorganic layer 111a may include an inorganic insulating material, but embodiments are not limited thereto. According to an embodiment, the first inorganic layer 111a may include an inorganic insulating material such as silicon oxynitride (SiOₓN_{y}).

Referring to FIG. 7C, a second inorganic layer 111b may be formed on the first inorganic layer 111a. The second inorganic layer 111b may cover the first inorganic layer 111a. The second inorganic layer 111b may have a similar shape to that of the first inorganic layer 111a previously described with reference to FIG. 7B. The second inorganic layer 111b may be in contact with (e.g., in direct contact with) the subpixel-defining layer 111.

The second inorganic layer 111b may include an inorganic insulating material. For example, the second inorganic layer 111b may include an inorganic insulating material such as silicon oxide (SiOₓ) or silicon nitride (SiNₓ). According to an embodiment, the second inorganic layer 111b and the subpixel-defining layer 111 may include the same material.

Referring to FIG. 7D, a photoresist PR may be formed on the second inorganic layer 111b. The photoresist PR may include an opening overlapping the electrode layer HM.

Referring to FIG. 7E, a portion of the second inorganic layer 111b may be etched by using the photoresist PR as a mask to form the air gap SPC. The air gap SPC may be a penetration hole penetrating (or passing) through the second inorganic layer 111b. The width SW1 of the air gap SPC may be less than the width W2 of the upper surface of the first inorganic layer 111a. A process of forming the air gap SPC may include a dry etching process.

The second inorganic layer 111b may contact (e.g., directly contact) the subpixel-defining layer 111 and may include the same material as the subpixel-defining layer 111, and thus may be a layer substantially the same as the subpixel-defining layer 111. For example, the second inorganic layer 111b may be a portion of the subpixel-defining layer 111 protruding from the upper surface of the subpixel-defining layer 111. Therefore, in the following description, the subpixel-defining layer 111 is considered as a layer including a lower portion as the subpixel-defining layer 117 as described above and an upper portion as the second inorganic layer 111b. For example, the electrode layer HM and the first inorganic layer 111a may be disposed on an upper surface of the lower portion of the subpixel-defining layer 111.

Referring to FIG. 7F, the first inorganic layer 111a (see FIG. 7E) may be removed (e.g., entirely removed) by using the photoresist PR as a mask.

A process of removing the first inorganic layer 111a (see FIG. 7E) may include a wet etching process. The first inorganic layer 111a (see FIG. 7E) may include a different material from the material included in the subpixel-defining layer 111. In case that an etchant and/or an etching gas applicable only to the first inorganic layer 111a (see FIG. 7E) is used, only the first inorganic layer 111a (see FIG. 7E) may be removed (e.g., entirely removed) without damaging the subpixel-defining layer 111. The trench TR may be defined as a space remaining after removing the first inorganic layer 111a (see FIG. 7E) and a portion of the upper portion of the subpixel-defining layer 111.

Because the trench TR is formed by disposing two inorganic layers on the electrode layer HM and partially removing the inorganic layers, the shape of the trench TR may be similar to that of the electrode layer HM. For example, the shape of the trench TR may be determined according to the shape of the electrode layer HM.

For example, as shown in FIG. 7F, in case that the electrode layer HM is formed in an approximate trapezoidal shape, in which the width of an upper surface is greater than the width of a lower surface, the trench TR may also be formed in an approximately trapezoidal shape in which the width of the upper surface is greater than the width of the lower surface.

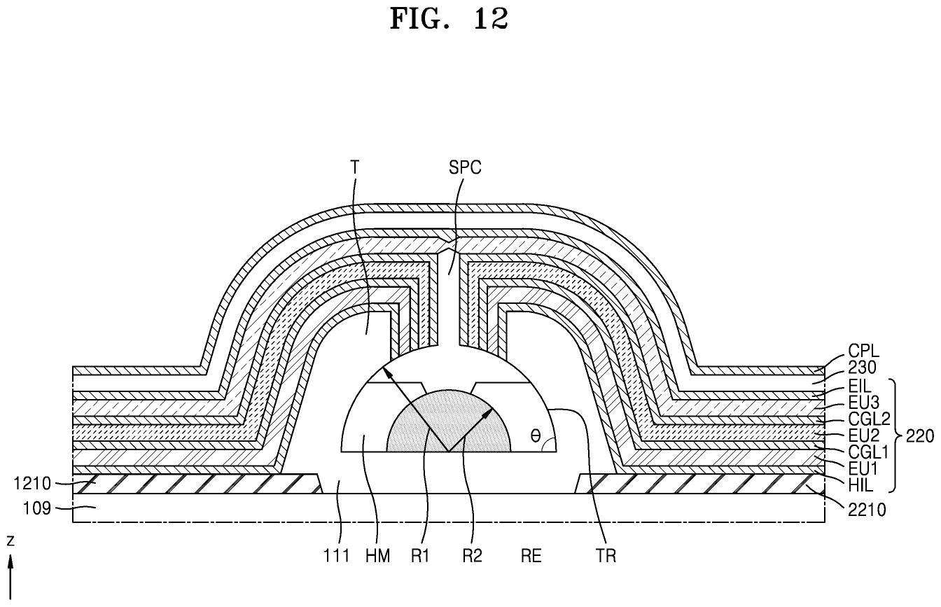

In another example, in case that the electrode layer HM is formed in a semi-circular shape, the trench TR may also be formed in a semi-circular shape or a substantially dome shape. This will be described later with reference to FIG. 12.

Thereafter, the photoresist PR may be removed.

Referring to FIG. 7G, a hole injection layer HIL may be formed on the first and second subpixel electrodes 1210 and 2210 and the subpixel-defining layer 111.

A process of forming the hole injection layer HIL may be as follows.

In the embodiment shown in FIG. 7F, the material of the hole injection layer HIL may be coated on the entire surface of a resultant structure formed by removing the photoresist PR (see FIG. 7F) from the embodiment shown in FIG. 7F. For example, the material of the hole injection layer HIL coated on the electrode layer HM may be removed by heat generated by applying a voltage to the electrode layer HM. For example, at least a portion of the hole injection layer HIL may contact a surface of the electrode layer HM or may be disposed above the electrode layer HM to be spaced apart from the electrode layer HM. For example, the removed portion may be repositioned in a space within the trench TR. Through the above process, the hole injection layer HIL may be discontinuous (or disconnected) in the air gap SPC. The portion of the material of the hole injection layer HIL removed by the electrode layer HM and repositioned in the trench TR may be included in the redistribution layer RE, as shown in FIG. 7G.

In another example, the hole injection layer HIL removed by the electrode layer HM may be removed (e.g., completely removed) without being rearranged.

As the hole injection layer HIL is formed, the shape of the air gap SPC may change.

As the hole injection layer HIL is formed, the width of the air gap SPC may be reduced. For example, a width SW2 of the air gap SPC after the hole injection layer HIL is formed may be less than a width SW1 (see FIG. 7F) of the air gap SPC before the hole injection layer HIL is formed.

As the hole injection layer HIL is formed, the height of the air gap SPC may be increased. For example, a height h2 of the air gap SPC after the hole injection layer HIL is formed may be greater than a height h1 (see FIG. 7F) of the air gap SPC before the hole injection layer HIL is formed. For example, as the hole injection layer HIL is formed, the air gap SPC may extend in the positive z-axis direction.

Referring to FIG. 7H, the first emitting unit EU1 and the first charge generation layer CGL1 may be formed on the hole injection layer HIL.

A process of forming the first emitting unit EU1 and the first charge generation layer CGL1 may be similar to the process of forming the hole injection layer HIL described above with reference to FIG. 7G. For example, the process of forming the first emitting unit EU1 and the first charge generation layer CGL1 may be as follows.

In the embodiments below, the materials of the first emitting unit EU1 and the first charge generating layer CGL1′ may be as the material of the first emitting unit EU1 and the material of the first charge generation layer CGL1′ instead of the materials included in both the first emitting unit EU1 and the first charge generating layer CGL1′.

In the embodiment shown in FIG. 7G, the materials of the first emitting unit EU1 and the first charge generation layer CGL1 may be coated on the entire surface. For example, the materials of the first emitting unit EU1 and the first charge generation layer CGL1 coated on the electrode layer HM may be removed by the heat generated by applying a voltage to the electrode layer HM. For example, at least a portion of the first emitting unit EU1 and the first charge generation layer CGL1 may be disposed above the electrode layer HM to be spaced apart from the electrode layer HM. For example, the removed portion may be repositioned in a space within the trench TR. Through the above process, the first emitting unit EU1 and the first charge generation layer CGL1 may be discontinuous (or disconnected) in the air gap SPC. The portion of the materials of the first emitting unit EU1 and the first charge generation layer CGL1 removed by the electrode layer HM and repositioned in the trench TR may be included in the redistribution layer RE, as shown in FIG. 7H.

In another example, the first emitting unit EU1 and the first charge generation layer CGL1 removed by the electrode layer HM may be removed (e.g., completely removed) without being rearranged.

The above-described process including coating on the entire surface, partial removal, and rearrangement may be performed simultaneously or separately for the first emitting unit EU1 and the first charge generation layer CGL1. According to an embodiment, the above-described process may include coating on the entire surface, partial removal, and rearrangement with respect to the first emitting unit EU1 and the first charge generation layer CGL1. In another example, the above-described process may include coating on the entire surface, partial removal, and rearrangement with respect to the first charge generation layer CGL1 after coating on the entire surface, partial removal, and rearrangement with respect to the first emitting unit EUL.

As the first emitting unit EU1 and the first charge generation layer CGL1 are formed, the shape of the air gap SPC may change.

As the first emitting unit EU1 and the first charge generation layer CGL1 are formed, the width of the air gap SPC may be reduced. For example, a width SW3 of the air gap SPC after the first emitting unit EU1 and the first charge generating layer CGL1 are formed may be less than the width SW2 (see FIG. 7G) of the air gap SPC before the first emitting unit EU1 and the first charge generating layer CGL1 are formed.

As the first emitting unit EU1 and the first charge generation layer CGL1 are formed, the height of the air gap SPC may be increased. For example, a width h3 of the air gap SPC after the first emitting unit EU1 and the first charge generating layer CGL1 are formed may be less than the height h2 (see FIG. 7G) of the air gap SPC before the first emitting unit EU1 and the first charge generating layer CGL1 are formed. For example, as the first emitting unit EU1 and the first charge generation layer CGL1 are formed, the air gap SPC may extend in the positive z-axis direction.

Referring to FIG. 7I, the second emitting unit EU2 and the second charge generation layer CGL2 may be formed on the first charge generating layer CGL1.

A process of forming the second emitting unit EU2 and the second charge generation layer CGL2 may be similar to the process of forming the first emitting unit EU1 and the first charge generating layer CGL1 described above with reference to FIG. 7H. For example, the process of forming the second emitting unit EU2 and the second charge generation layer CGL2 may be as follows.

In the embodiments below, the materials of the second emitting unit EU2 and the second charge generating layer CGL2′ may be as the material of the second emitting unit EU2 and the material of the second charge generation layer CGL2′ instead of the materials included in both the second emitting unit EU2 and the second charge generating layer CGL2′.

In the embodiment shown in FIG. 7H, the materials of the second emitting unit EU2 and the second charge generation layer CGL2 may be coated on the entire surface. For example, the materials of the second emitting unit EU2 and the second charge generation layer CGL2 coated on the electrode layer HM may be removed by the heat generated by applying a voltage to the electrode layer HM. For example, at least a portion of the second emitting unit EU2 and the second charge generation layer CGL2 may be disposed above the electrode layer HM to be spaced apart from the electrode layer HM. For example, the removed portion may be repositioned in a space within the trench TR. Through the above process, the second emitting unit EU2 and the second charge generation layer CGL2 may be discontinuous (or disconnected) in the air gap SPC. The portion of the materials of the second emitting unit EU2 and the second charge generation layer CGL2 removed by the electrode layer HM and repositioned in the trench TR may be included in the redistribution layer RE, as shown in FIG. 7I.

In another example, the second emitting unit EU2 and the second charge generation layer CGL2 removed by the electrode layer HM may be removed (e.g., completely removed) without being rearranged.

The above-described process including coating on the entire surface, partial removal, and rearrangement may be performed simultaneously or separately for the second emitting unit EU2 and the second charge generation layer CGL2. According to an embodiment, the above-described process may include coating on the entire surface, partial removal, and rearrangement with respect to the second emitting unit EU2 and the second charge generation layer CGL2. In another example, the above-described process may include coating on the entire surface, partial removal, and rearrangement with respect to the second charge generation layer CGL2 after coating on the entire surface, partial removal, and rearrangement with respect to the second emitting unit EU2.

As the second emitting unit EU2 and the second charge generation layer CGL2 are formed, the shape of the air gap SPC may change.

As the second emitting unit EU2 and the second charge generation layer CGL2 are formed, the width of the air gap SPC may be reduced. For example, a width SW4 of the air gap SPC after the second emitting unit EU2 and the second charge generation layer CGL2 are formed may be less than the width SW3 (see FIG. 7H) of the air gap SPC before the second emitting unit EU2 and the second charge generation layer CGL2 are formed.

As the second emitting unit EU2 and the second charge generation layer CGL2 are formed, the height of the air gap SPC may be increased. For example, a height h4 of the air gap SPC after the second emitting unit EU2 and the second charge generation layer CGL2 are formed may be greater than the height h3 (see FIG. 7H) of the air gap SPC before the second emitting unit EU2 and the second charge generation layer CGL2 are formed. For example, as the second emitting unit EU2 and the second charge generation layer CGL2 are formed, the air gap SPC may extend in the positive z-axis direction.

Referring to FIG. 7J, the third emitting unit EU3 and the electron injection layer EIL may be formed on the second charge generation layer CGL2.

The third emitting unit EU3 may be disposed on the second charge generation layer CGL2. The third emitting unit EU3 may be formed by coating the material of the third emitting unit EU3 on the entire surface of the embodiment shown in FIG. 7I.

The third emitting unit EU3 may be formed to be connected without being discontinuous (or disconnected) in the air gap SPC. After the hole injection layer HIL, the first and second emitting units EU1 and EU2, and the first and second charge generation layers CGL1 and CGL2 are formed, the width of the air gap SPC may have decreased. Accordingly, in case that a sufficient thickness (for example, a thickness greater than or substantially equal to the width SW4 of the air gap SPC) is ensured and the material of the third emitting unit EU3 is coated, the third emitting unit EU3 may not be discontinuous (or disconnected) in the air gap SPC. A lower surface of a portion of the third emitting unit EU3 overlapping the air gap SPC may define the upper surface of the air gap SPC.

The portion of the third emitting unit EU3 defining the upper surface of the air gap SPC may have a different thickness from the other portion. For example, the third emitting unit EU3 may be formed to be concave in a thickness direction in a region overlapping the air gap SPC.

The electron injection layer EIL may be formed on the third emitting unit EU3. Similar to the third emitting unit EU3, the electron injection layer EIL may not be discontinuous (or disconnected) in a region overlapping the air gap SPC.

Thereafter, the embodiment shown in FIG. 3 may be implemented by disposing the opposite electrode 230 (see FIG. 3) and the capping layer CPL (see FIG. 3) on the electron injection layer EIL.

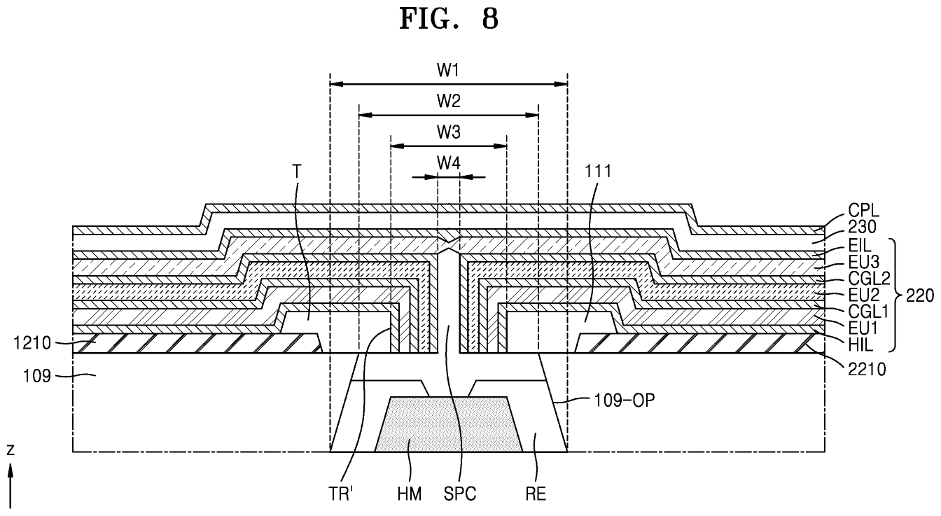

FIG. 8 is a magnified schematic cross-sectional view of a portion of the display apparatus 1 according to an embodiment.

Because the embodiment of FIG. 8 is the same as the embodiment of FIG. 3 except for differences in a trench TR′, an air gap SPC, and an opening 109-OP of the second organic insulating layer 109, the differences will now be focused on and described.

The trench TR′ of the subpixel-defining layer 111 may be a through-type hole penetrating (or passing) through the subpixel-defining layer 111. The second organic insulating layer 109 may include the opening 109-OP overlapping the trench TR′.

The subpixel-defining layer 111 may include a tip portion T protruding toward the trench TR′. For example, the subpixel-defining layer 111 may include a tip portion T protruding toward the trench TR′ from a point where the lower surface of the subpixel-defining layer 111 and the side surface of the second organic insulating layer 109 meet.

FIG. 8 shows that the thickness of the tip portion T is constant, but embodiments are not limited thereto. In another example, the thickness of the tip portion T may decrease in a direction (e.g., a direction toward the trench TR′).

A width W3 of the trench TR′ may be less than a width W2 of an upper end portion of the opening 109-OP of the second organic insulating layer 109. For example, the second organic insulating layer 109 may have an undercut structure. FIG. 8 shows that the width W3 of the trench TR′ is constant, but embodiments are not limited thereto. In another example, the width W3 of the trench TR′ may decrease in a direction (e.g., the positive z-axis direction).

The opening 109-OP of the second organic insulating layer 109 may have a shape in which a width decreases in a direction. For example, the width of the opening 109-OP of the second organic insulating layer 109 may decrease in the positive z-axis direction. According to an embodiment, the opening 109-OP of the second organic insulating layer 109 may have a substantially trapezoidal shape in which a width W1 of a lower end portion is greater than a width W2 of an upper end portion.

Although FIG. 8 shows that the width W1 of the lower end portion of the opening 109-OP of the second organic insulating layer 109 is greater than the width W2 of the upper end portion of the opening 109-OP of the second organic insulating layer 109, embodiments are not limited thereto. As another example, the width of the opening 109-OP of the second organic insulating layer 109 may decrease in the negative z-axis direction. For example, the opening 109-OP of the second organic insulating layer 109 may have a substantially trapezoidal shape in which a width W1 of a lower end portion is less than a width W2 of an upper end portion. In another example, the width of the opening 109-OP of the second organic insulating layer 109 may be constant in the positive and negative z-axis directions. For example, the opening 109-OP of the second organic insulating layer 109 may have a substantially rectangular shape in which a width W1 of a lower end portion is substantially equal to a width W2 of an upper end portion.

The shape of the opening 109-OP of the second organic insulating layer 109 may be similar to the shape of the trench TR (see FIG. 3) described above with reference to FIG. 3, and various modification thereto may be made.

A portion of the trench TR′ of the subpixel-defining layer 111 may be included in the air gap SPC. For example, a portion of the trench TR′ of the subpixel-defining layer 111 may be filled with the hole injection layer HIL, the first and second emitting units EU1 and EU2, and the first and second charge generation layers CGL1 and CGL2, and the remaining unfilled portion may be included in the air gap SPC.

The air gap SPC may be understood as a space including a portion of the trench TR′ and a space between a stack of the hole injection layer HIL, the first emitting unit EU1, the first charge generation layer CGL1, the second emitting unit EU2, and the second charge generation layer CGL2.

The electrode layer HM may be disposed within the opening 109-OP of the second organic insulating layer 109. The electrode layer HM may be spaced apart from the inner side surfaces of the second organic insulating layer 109. The shape of the electrode layer HM may be similar to, but smaller than, the shape of the opening 109-OP of the second organic insulating layer 109. For example, like the shape of the opening 109-OP of the second organic insulating layer 109, the electrode layer HM may have a substantially trapezoidal shape in which an upper surface is wider than a lower surface. However, embodiments are not limited thereto, and the shape of the electrode layer HM may be variously modified.

The redistribution layer RE may be disposed between the electrode layer HM and the inner side surfaces of the second organic insulating layer 109. The redistribution layer RE may be a structure in which respective portions of the hole injection layer HIL, the first emitting unit EU1, the first charge generation layer CGL1, the second emitting unit EU2, and the second charge generation layer CGL2 broken (or disconnected/separated) in the air gap SPC are stacked. Accordingly, the redistribution layer RE may include at least one of the hole injection layer HIL, the first emitting unit EU1, the first charge generation layer CGL1, the second emitting unit EU2, and the second charge generation layer CGL2.

The redistribution layer RE may expose a portion of the upper surface of the electrode layer HM.

Although the hole injection layer HIL, the first emitting unit EU1, the first charge generation layer CGL1, the second emitting unit EU2, and the second charge generation layer CGL2 disposed on the upper surface of the redistribution layer RE and the tip portion T are illustrated as being spaced apart from one another in FIG. 8, embodiments are not limited thereto. In another example, the hole injection layer HIL, the first emitting unit EU1, the first charge generation layer CGL1, the second emitting unit EU2, and the second charge generation layer CGL2 disposed on the upper surface of the redistribution layer RE and the tip portion T may contact one another.

Because the redistribution layer RE may include the first and second charge generation layers CGL1 and CGL2, the redistribution layer RE may include a conductive material. However, because the redistribution layer RE may include the hole injection layer HIL and the first and second emitting units EU1 and EU2, the redistribution layer RE may not be conductive as a whole. Therefore, in case that the upper surface of the redistribution layer RE is in contact with (e.g., in direct contact with) the first and second charge generation layers CGL1 and CGL2, current may not flow through the first and second charge generation layers CGL1 and CGL2, the redistribution layer RE, and the electrode layer HM.

In the embodiment shown in FIG. 8, the opening 109-OP of the second organic insulating layer 109 may perform a similar role to that of the trench TR described above with reference to FIG. 3. The opening 109-OP of the second organic insulating layer 109 may provide a space in which the electrode layer HM is disposed, and may provide a space in which the redistribution layer RE is disposed. For example, by forming the opening 109-OP in the second organic insulating layer 109, the embodiment of FIG. 8 may enable the subpixel-defining layer 111 to have a less height than the embodiment shown in FIG. 3.

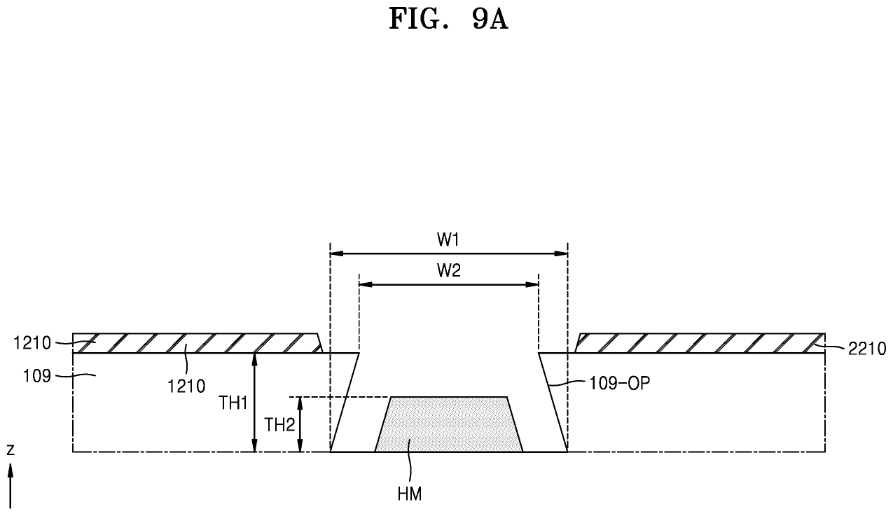

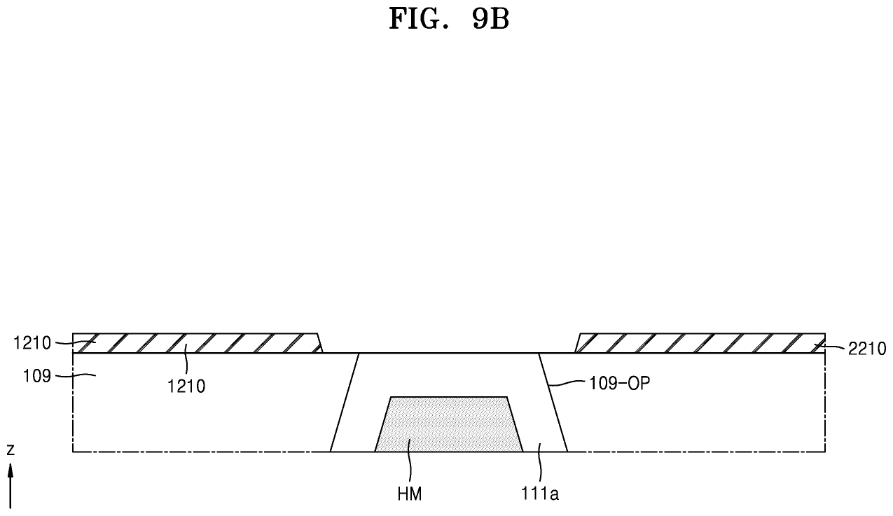

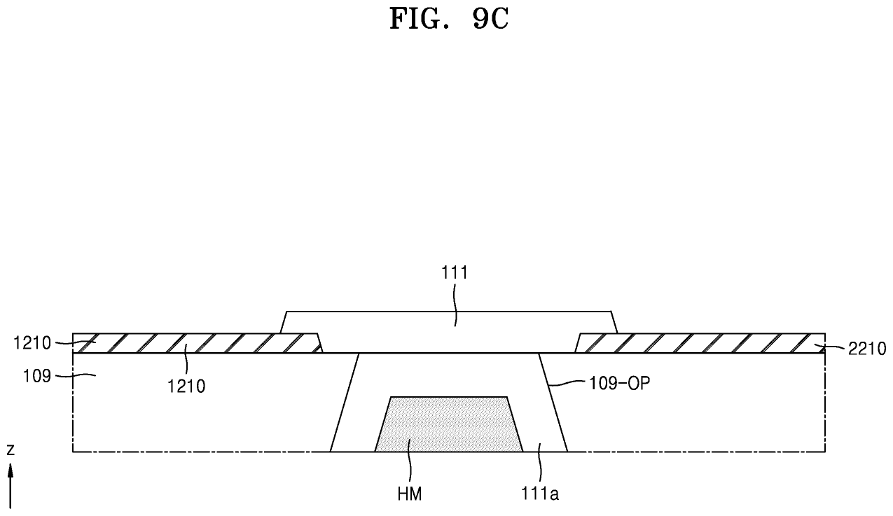

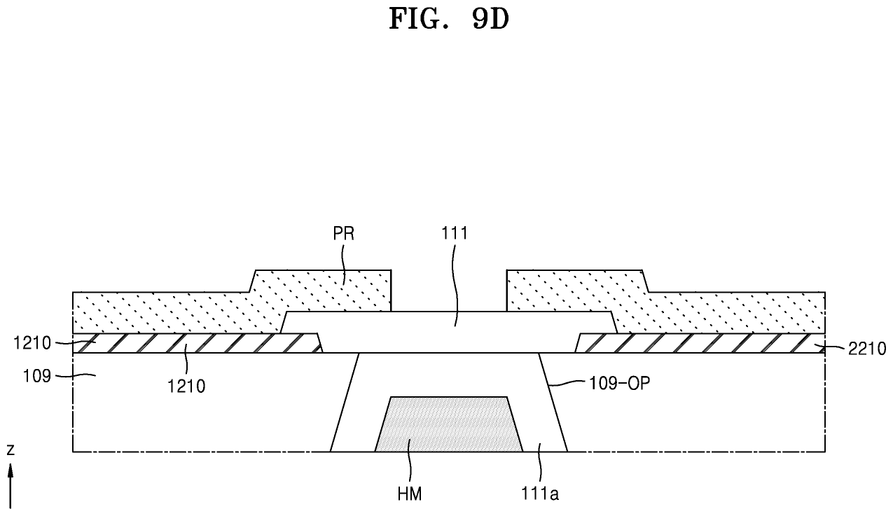

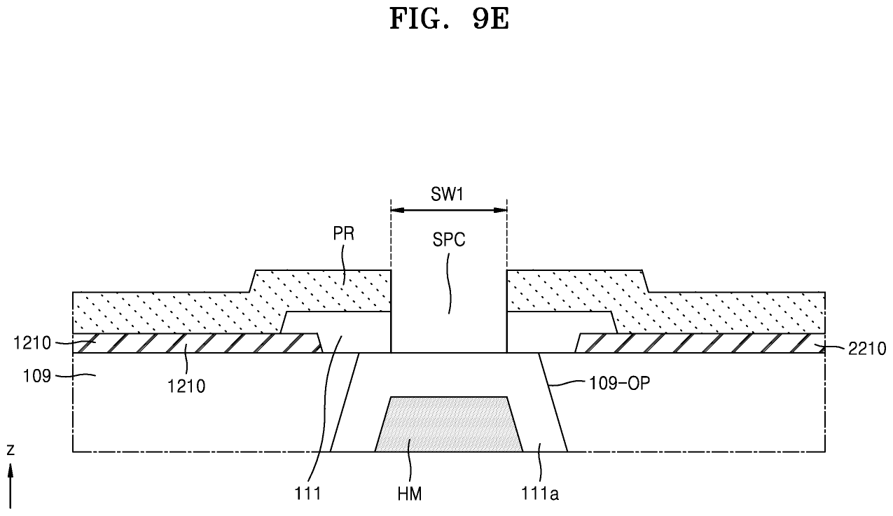

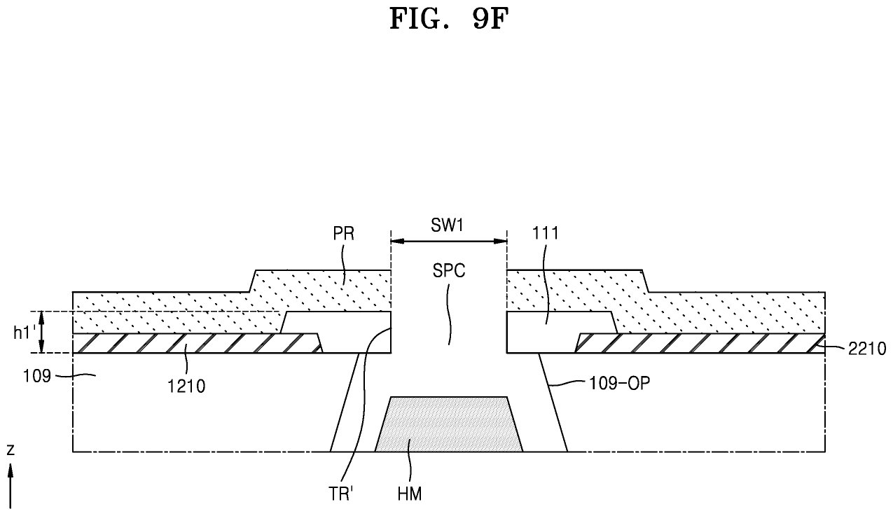

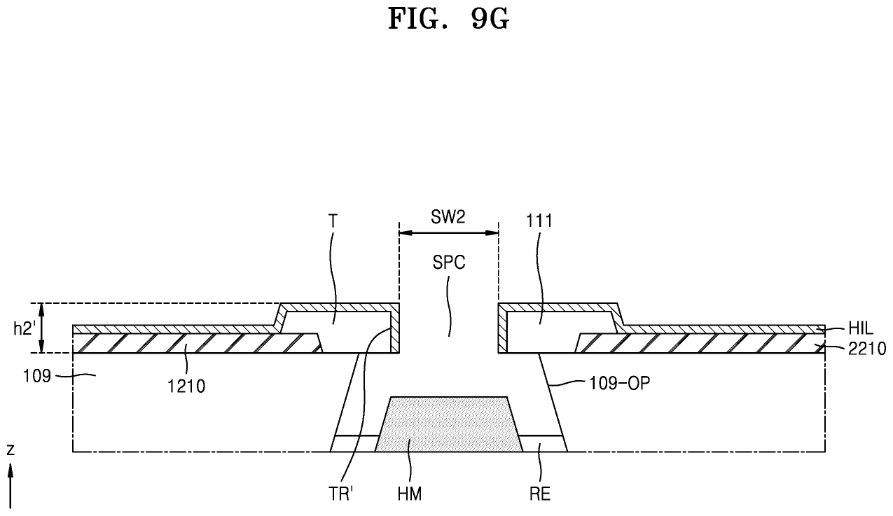

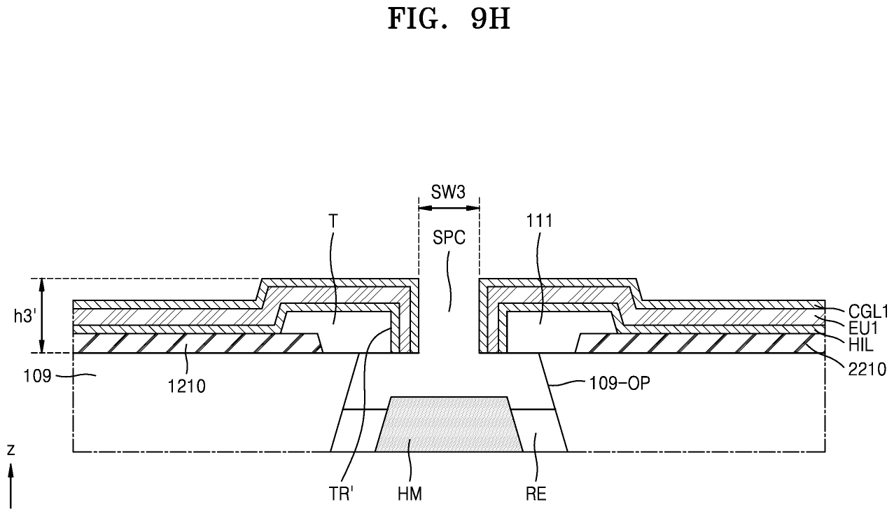

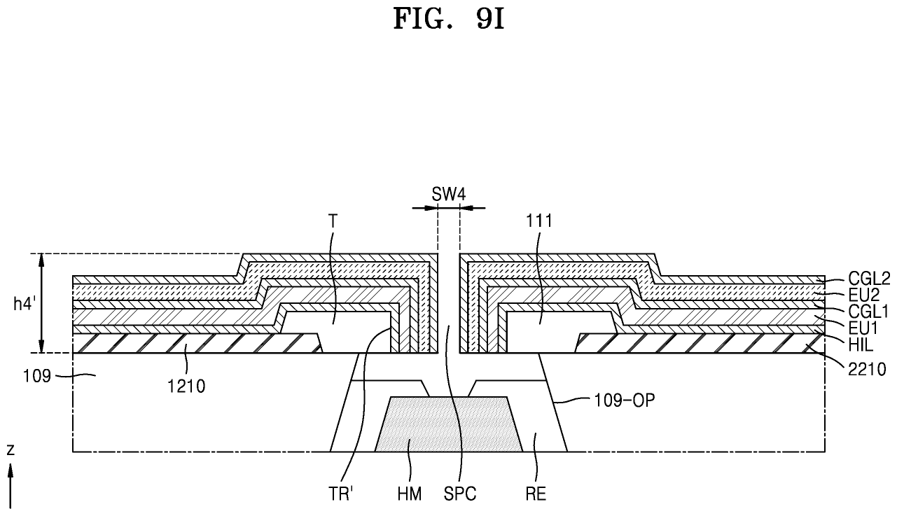

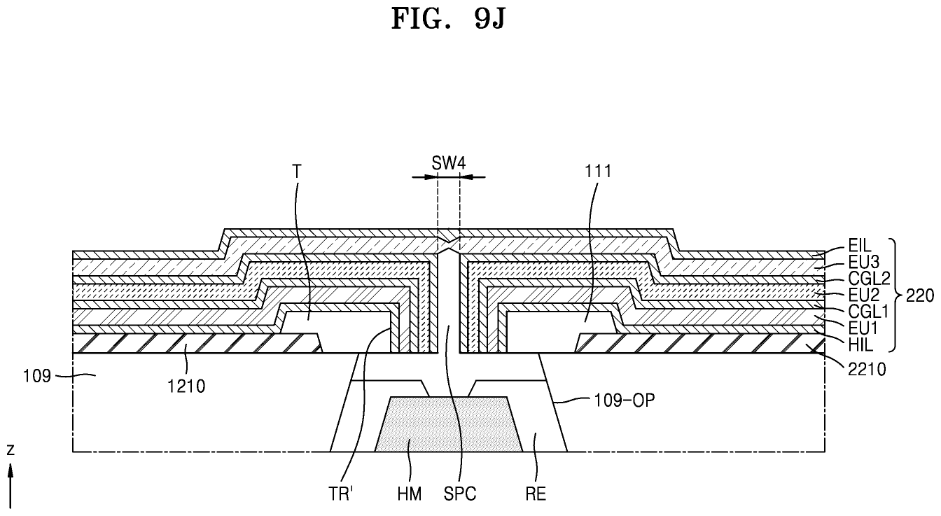

FIGS. 9A, 9B, 9C, 9D, 9E, 9F, 9G, 9H, 9I, and 9J are schematic cross-sectional views illustrating a manufacturing method according to an embodiment.

Referring to FIG. 9A, the first and second subpixel electrodes 1210 and 2210 may be disposed to be spaced apart from each other on the second organic insulating layer 109.

The second organic insulating layer 109 may include the opening 109-OP arranged between the first and second subpixel electrodes 1210 and 2210. The opening 109-OP may be in the form of a blind hole that does not pass through the second organic insulating layer 109, but embodiments are not limited thereto. In another example, the opening 109-OP may be a through hole.

A width W3 of a lower surface of the opening 109-OP may be greater than a width W2 of an upper surface of the opening 109-OP. For example, the opening 109-OP may take the shape of an approximately trapezoid in which a lower end portion is wider than an upper end portion.

The electrode layer HM may be disposed within the opening 109-OP of the second organic insulating layer 109. The electrode layer HM may have a similar shape as the opening 109-OP of the second organic insulating layer 109 and may be smaller than the second organic insulating layer 109. For example, the electrode layer HM may have the shape of an approximately trapezoid in which a lower end portion is wider than an upper end portion. A thickness TH2 of the electrode layer HM may be less than a thickness TH1 of the opening 109-OP of the second organic insulating layer 109.

Referring to FIG. 9B, the first inorganic layer 111a may be formed in the opening 109-OP of the second organic insulating layer 109. The first inorganic layer 111a may cover the electrode layer HM. Similar to the electrode layer HM, a width of the lower surface of the first inorganic layer 111a may be greater than a width of the upper surface thereof. The upper surface of the first inorganic layer 111a may be positioned on the same plane as the upper surface of the second organic insulating layer 109.

The first inorganic layer 111a may include an inorganic insulating material, but embodiments are not limited thereto. According to an embodiment, the first inorganic layer 111a may include an inorganic insulating material such as silicon oxynitride (SiOₓN_{y}).

Referring to FIG. 9C, the subpixel-defining layer 111 may be formed on the second inorganic layer 111b. The subpixel-defining layer 111 may cover the first inorganic layer 111a. The subpixel-defining layer 111 may cover edge regions (or edges) of the first and second subpixel electrodes 1210 and 2210. The subpixel-defining layer 111 may include side surfaces forward tapered with respect to respective upper surfaces of the first and second subpixel electrodes 1210 and 2210.

The subpixel-defining layer 111 may include an organic insulating material. For example, the subpixel-defining layer 111 may include an inorganic insulating material such as silicon oxide (SiOₓ) or silicon nitride (SiNₓ). According to an embodiment, the subpixel-defining layer 111 may include a different same material from that included in the first inorganic layer 111a.

Referring to FIG. 9D, the photoresist PR may be formed on the subpixel-defining layer 111. The photoresist PR may include an opening overlapping the electrode layer HM.

Referring to FIG. 9E, the trench TR′ may be formed by removing a portion of the subpixel-defining layer 111 by using the photoresist PR as a mask.

A process of forming the trench TR′ may include a dry etching process. The trench TR′ may be a through hole. A width SW1 of the trench TR′ may be less than the width of the upper surface of the first inorganic layer 111a. In FIG. 9E, the width SW1 of the trench TR′ is shown as being constant in FIG. 9E. In another example, the width SW1 of the trench TR′ may decrease in a direction (e.g., the positive z-axis direction).

Referring to FIG. 9F, the first inorganic layer 111a (see FIG. 9D) may be removed (e.g., entirely removed).

A process of removing the first inorganic layer 111a (see FIG. 9E) may include a wet etching process. The first inorganic layer 111a (see FIG. 9E) may include a different material from the material included in the subpixel-defining layer 111. Accordingly, in case that an etchant or an etching gas applicable only to the first inorganic layer 111a (see FIG. 9E) is used, the first inorganic layer 111a (see FIG. 9E) may be removed (e.g., entirely removed) without damaging the subpixel-defining layer 111.

Unlike the relationship between the trench TR (see FIG. 7F) and the electrode layer HM (see FIG. 7F) shown in FIG. 7F (e.g., a relationship regarding similar shapes), the opening 109-OP of the second organic insulating layer 109 and the electrode layer HM may have different shapes. For example, the shape of the opening 109-OP of the second organic insulating layer 109 may be independently determined regardless of the shape of the electrode layer HM, because a formation process of the trench TR and a formation process of the opening 109-OP of the second organic insulating layer 109 shown in FIG. 7F are different. According to an embodiment, the opening 109-OP of the second organic insulating layer 109 may have a dome shape, and the electrode layer HM may have a substantially trapezoidal shape in which an upper surface is narrower than a lower surface. However, embodiments are not limited thereto, and the respective shapes of the opening 109-OP and the electrode layer HM may be variously modified.

In the operations of the process shown in FIGS. 9E and 9F, the trench TR′ and the air gap SPC may refer to the same space. For example, the trench TR′ and the air gap SPC may refer to a through hole formed in the subpixel-defining layer 111.

Thereafter, the photoresist PR may be removed.

Referring to FIG. 9G, a hole injection layer HIL may be formed on the first and second subpixel electrodes 1210 and 2210 and the subpixel-defining layer 111.

A process of forming the hole injection layer HIL may be as follows.

In the embodiment shown in FIG. 9F, the material of the hole injection layer HIL may be coated on the entire surface of a resultant structure formed by removing the photoresist PR (see FIG. 9F) from the embodiment shown in FIG. 9F. For example, the material of the hole injection layer HIL coated on the electrode layer HM may be removed by heat generated by applying a voltage to the electrode layer HM. For example, at least a portion of the hole injection layer HIL may contact a surface of the electrode layer HM or may be disposed above the electrode layer HM to be spaced apart from the electrode layer HM. For example, the removed portion may be repositioned in a space within the trench TR′. Through the above process, the hole injection layer HIL may be discontinuous (or disconnected) in the air gap SPC. The portion of the material of the hole injection layer HIL removed by the electrode layer HM and repositioned in the trench TR may be included in the redistribution layer RE, as shown in FIG. 9G.

In another example, the hole injection layer HIL removed by the electrode layer HM may be removed (e.g., completely removed) without being rearranged.

As the hole injection layer HIL is formed, the shape of the air gap SPC may change.

As the hole injection layer HIL is formed, the width of the air gap SPC may be reduced. For example, a width SW2 of the air gap SPC after the hole injection layer HIL is formed may be less than a width SW1 (see FIG. 9F) of the air gap SPC before the hole injection layer HIL is formed.

As the hole injection layer HIL is formed, the height of the air gap SPC may be increased. For example, a height h2′ of the air gap SPC after the hole injection layer HIL is formed may be greater than a height h1′ (see FIG. 9F) of the air gap SPC before the hole injection layer HIL is formed. For example, as the hole injection layer HIL is formed, the air gap SPC may extend in the positive z-axis direction.

Due to the change in the shape of the air gap SPC, in the operations of the process described with reference to FIGS. 9G, 9H, 9I, and 9J, spaces indicated by the trench TR′ and the air gap SPC may be different, unlike in the operations of the process shown with reference to FIGS. 9E and 9F.

Referring to FIG. 9H, the first emitting unit EU1 and the first charge generation layer CGL1 may be formed on the hole injection layer HIL.

A process of forming the first emitting unit EU1 and the first charge generation layer CGL1 may be similar to the process of forming the hole injection layer HIL described above with reference to FIG. 9G. For example, the process of forming the first emitting unit EU1 and the first charge generation layer CGL1 may be as follows.

In the embodiments below, the materials of the first emitting unit EU1 and the first charge generating layer CGL1′ may be as the material of the first emitting unit EU1 and the material of the first charge generation layer CGL1′ instead of the materials included in both the first emitting unit EU1 and the first charge generating layer CGL1′.

In the embodiment shown in FIG. 9G, the materials of the first emitting unit EU1 and the first charge generation layer CGL1 may be coated on the entire surface. For example, the materials of the first emitting unit EU1 and the first charge generation layer CGL1 coated on the electrode layer HM may be removed by the heat generated by applying a voltage to the electrode layer HM. For example, at least a portion of the first emitting unit EU1 and the first charge generation layer CGL1 may be disposed above the electrode layer HM to be spaced apart from the electrode layer HM. For example, the removed portion may be repositioned in a space within the trench TR′. Through the above process, the first emitting unit EU1 and the first charge generation layer CGL1 may be discontinuous (or disconnected) in the air gap SPC. The portion of the materials of the first emitting unit EU1 and the first charge generation layer CGL1 removed by the electrode layer HM and repositioned in the trench TR may be included in the redistribution layer RE, as shown in FIG. 9H.

In another example, the first emitting unit EU1 and the first charge generation layer CGL1 removed by the electrode layer HM may be removed (e.g., completely removed) without being rearranged.

The above-described process including coating on the entire surface, partial removal, and rearrangement may be performed simultaneously or separately for the first emitting unit EU1 and the first charge generation layer CGL1. According to an embodiment, the above-described process may include coating on the entire surface, partial removal, and rearrangement with respect to the first emitting unit EU1 and the first charge generation layer CGL1. In another example, the above-described process may include coating on the entire surface, partial removal, and rearrangement with respect to the first charge generation layer CGL1 after coating on the entire surface, partial removal, and rearrangement with respect to the first emitting unit EUL.

As the first emitting unit EU1 and the first charge generation layer CGL1 are formed, the shape of the air gap SPC may change.

As the first emitting unit EU1 and the first charge generation layer CGL1 are formed, the width of the air gap SPC may be reduced. For example, a width SW3 of the air gap SPC after the first emitting unit EU1 and the first charge generating layer CGL1 are formed may be less than the width SW2 (see FIG. 9G) of the air gap SPC before the first emitting unit EU1 and the first charge generating layer CGL1 are formed.

As the first emitting unit EU1 and the first charge generation layer CGL1 are formed, the height of the air gap SPC may be increased. For example, a width h3′ of the air gap SPC after the first emitting unit EU1 and the first charge generating layer CGL1 are formed may be less than the height h2′ (see FIG. 9G) of the air gap SPC before the first emitting unit EU1 and the first charge generating layer CGL1 are formed. For example, as the first emitting unit EU1 and the first charge generation layer CGL1 are formed, the air gap SPC may extend in the positive z-axis direction.

Referring to FIG. 9I, the second emitting unit EU2 and the second charge generation layer CGL2 may be formed on the first charge generating layer CGL1.

A process of forming the second emitting unit EU2 and the second charge generation layer CGL2 may be similar to the process of forming the first emitting unit EU1 and the first charge generating layer CGL1 described above with reference to FIG. 9H. For example, the process of forming the second emitting unit EU2 and the second charge generation layer CGL2 may be as follows.

In the embodiments below, the materials of the second emitting unit EU2 and the second charge generating layer CGL2′ may be as the material of the second emitting unit EU2 and the material of the second charge generation layer CGL2′ instead of the materials included in both the second emitting unit EU2 and the second charge generating layer CGL2′.

In the embodiment shown in FIG. 9H, the materials of the second emitting unit EU2 and the second charge generation layer CGL2 may be coated on the entire surface. For example, the materials of the second emitting unit EU2 and the second charge generation layer CGL2 coated on the electrode layer HM may be removed by the heat generated by applying a voltage to the electrode layer HM. For example, at least a portion of the second emitting unit EU2 and the second charge generation layer CGL2 may be disposed above the electrode layer HM to be spaced apart from the electrode layer HM. For example, the removed portion may be repositioned in a space within the trench TR′. Through the above process, the second emitting unit EU2 and the second charge generation layer CGL2 may be discontinuous (or disconnected) in the air gap SPC. The portion of the materials of the second emitting unit EU2 and the second charge generation layer CGL2 removed by the electrode layer HM and repositioned in the trench TR may be included in the redistribution layer RE, as shown in FIG. 9I.

In another example, the second emitting unit EU2 and the second charge generation layer CGL2 removed by the electrode layer HM may be removed (e.g., completely removed) without being rearranged.

The above-described process including coating on the entire surface, partial removal, and rearrangement may be performed simultaneously or separately for the second emitting unit EU2 and the second charge generation layer CGL2. According to an embodiment, the above-described process may include coating on the entire surface, partial removal, and rearrangement with respect to the second emitting unit EU2 and the second charge generation layer CGL2. In another example, the above-described process may include coating on the entire surface, partial removal, and rearrangement with respect to the second charge generation layer CGL2 after coating on the entire surface, partial removal, and rearrangement with respect to the second emitting unit EU2.

As the second emitting unit EU2 and the second charge generation layer CGL2 are formed, the shape of the air gap SPC may change.

As the second emitting unit EU2 and the second charge generation layer CGL2 are formed, the width of the air gap SPC may be reduced. For example, a width SW4 of the air gap SPC after the second emitting unit EU2 and the second charge generation layer CGL2 are formed may be less than the width SW3 (see FIG. 9H) of the air gap SPC before the second emitting unit EU2 and the second charge generation layer CGL2 are formed.

As the second emitting unit EU2 and the second charge generation layer CGL2 are formed, the height of the air gap SPC may be increased. For example, a height h4′ of the air gap SPC after the second emitting unit EU2 and the second charge generation layer CGL2 are formed may be greater than the height h3′ (see FIG. 9H) of the air gap SPC before the second emitting unit EU2 and the second charge generation layer CGL2 are formed. For example, as the second emitting unit EU2 and the second charge generation layer CGL2 are formed, the air gap SPC may extend in the positive z-axis direction.

Referring to FIG. 9J, the third emitting unit EU3 and the electron injection layer EIL may be formed on the second charge generation layer CGL2.

The third emitting unit EU3 may be disposed on the second charge generation layer CGL2. The third emitting unit EU3 may be formed by coating the material of the third emitting unit EU3 on the entire surface of the embodiment shown in FIG. 9I.

The third emitting unit EU3 may be formed to be connected without being broken (or disconnected/separated) in the air gap SPC. After the hole injection layer HIL, the first and second emitting units EU1 and EU2, and the first and second charge generation layers CGL1 and CGL2 are formed, the width of the air gap SPC may have decreased. Accordingly, in case that a sufficient thickness (for example, a thickness greater than or substantially equal to the width SW4 of the air gap SPC) is ensured and the material of the third emitting unit EU3 is coated, the third emitting unit EU3 may not be discontinuous (or disconnected) in the air gap SPC. A lower surface of a portion of the third emitting unit EU3 overlapping the air gap SPC may define the upper surface of the air gap SPC.

The portion of the third emitting unit EU3 defining the upper surface of the air gap SPC may have a different thickness from the other portion. For example, the third emitting unit EU3 may be formed to be concave in a thickness direction in a region overlapping the air gap SPC.

The electron injection layer EIL may be formed on the third emitting unit EU3. Similar to the third emitting unit EU3, the electron injection layer EIL may not be discontinuous (or disconnected) in a region overlapping the air gap SPC.

Thereafter, the embodiment shown in FIG. 8 may be implemented by disposing the opposite electrode 230 (see FIG. 8) and the capping layer CPL (see FIG. 8) on the electron injection layer EIL.

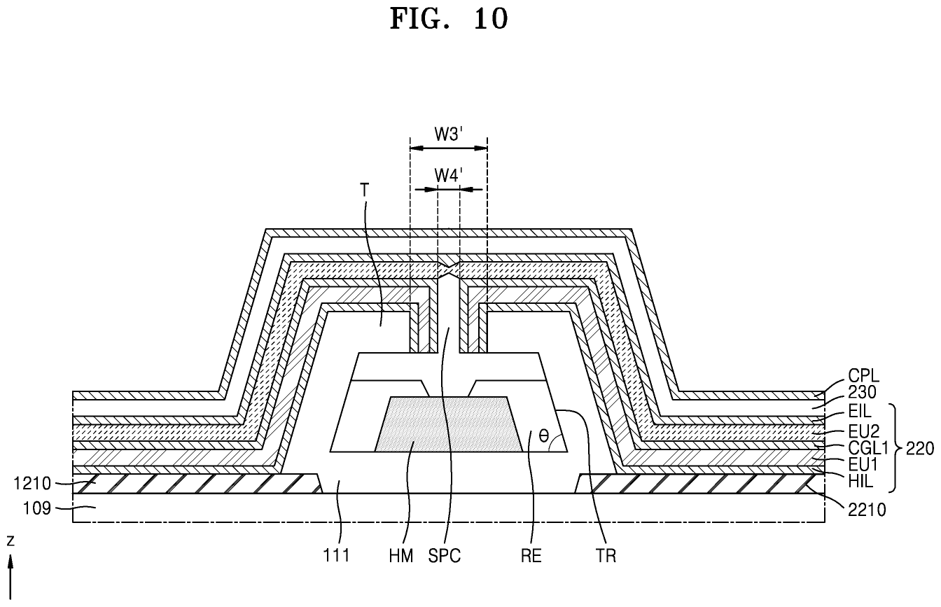

Because the embodiment of FIG. 10 is the same as the embodiment of FIG. 3 except for the characteristics of the intermediate layer 220, differences therebetween will now be focused on and described.

The intermediate layer 220 may include a hole injection layer, emitting units, at least one charge generation layer, and an electron injection layer. For example, the intermediate layer 220 may include the hole injection layer HIL, the first and second emitting units EU1 and EU2, the first charge generation layers CGL1, and the electron injection layer EIL.

The first charge generation layer CGL1 may be disposed between the first and second emitting units EU1 and EU2.

The intermediate layer 220 may be disposed on the first and second subpixel electrodes 1210 and 2210 and the subpixel-defining layer 111. The hole injection layer HIL, the first emitting unit EU1, and the first charge generation layer CGL1 in the intermediate layers 220 may be broken (or disconnected/separated) in a region overlapping the trench TR. For example, the hole injection layer HIL, the first emitting unit EU1, and the first charge generation layer CGL1 may be broken (or disconnected/separated) in the air gap SPC and thus may define the air gap SPC.

Respective portions of the hole injection layer HIL, the first emitting unit EU1, and the first charge generation layer CGL1 may be disposed on the upper surface and side surfaces of the tip portion T of the subpixel-defining layer 111.

A shape in which some of the constituent layers of the above-described intermediate layer 220 are discontinuous (or disconnected) near the air gap SPC may be similar to that described above with reference to FIG. 3.

As the hole injection layer HIL, the first emitting unit EU1, and the first charge generation layer CGL1 are stacked on one another, the width of the air gap SPC may be reduced. For example, the distance W3′ between the tip portions T, which is the width of the air gap SPC, before the hole injection layer HIL is disposed, may be greater than the width W4′ of the air gap SPC after the second charge generation layer CGL2 is disposed.

The second emitting unit EU2, the electron injection layer EIL, the opposite electrode 230, and the capping layer CPL may be disposed on the first charge generation layer CGL1. The second emitting unit EU2, the electron injection layer EIL, the opposite electrode 230, and the capping layer CPL may be connected in regions overlapping the trench TR.

A shape in which some of the constituent layers of the above-described intermediate layer 220 are continuous near the air gap SPC may be similar to that described above with reference to FIG. 3.

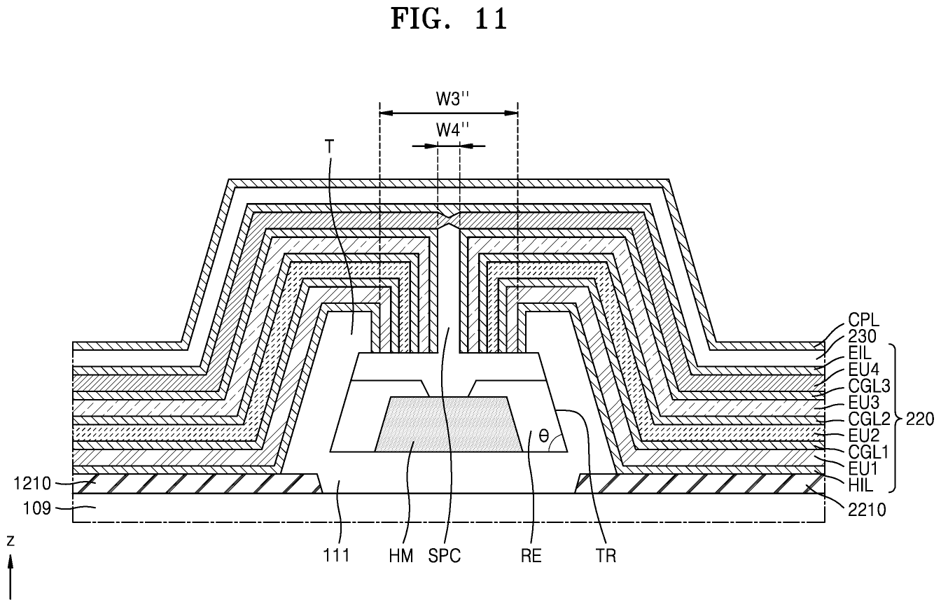

FIG. 11 is a magnified schematic cross-sectional view of a portion of the display apparatus 1 according to an embodiment.

Because the embodiment of FIG. 11 is the same as the embodiment of FIG. 3 except for the characteristics of the intermediate layer 220, differences therebetween will now be focused on and described.

The intermediate layer 220 may include a hole injection layer, emitting units, at least one charge generation layer, and an electron injection layer. For example, the intermediate layer 220 may include a hole injection layer HIL, first, second, third, and fourth emitting units EU1, EU2, EU3, and EU4, first, second, and third charge generation layers CGL1, CGL2, and CGL3, and an electron injection layer EIL.

The first, second, and third charge generation layers CGL1, CGL2, and CGL3 may be interposed between adjacent layers of the first, second, third, and fourth emitting units EU1, EU2, EU3, and EU4. For example, the first charge generation layer CGL1 may be disposed between the first and second emitting units EU1 and EU2. The second charge generation layer CGL2 may be disposed between the second and third emitting units EU2 and EU3. The third charge generation layer CGL3 may be disposed between the third and fourth emitting units EU3 and EU4.

The intermediate layer 220 may be disposed on the first and second subpixel electrodes 1210 and 2210 and the subpixel-defining layer 111. The hole injection layer HIL, the first, second, and third emitting units EU1, EU2, and EU3, and the first, second, and third charge generation layers CGL1, CGL2, and CGL3 in the intermediate layers 220 may be broken (or disconnected/separated) in regions overlapping the trench TR. For example, the hole injection layer HIL, the first emitting unit EU1, and the first charge generation layer CGL1 may be broken (or disconnected/separated) in the air gap SPC and thus may define the air gap SPC.

Respective portions of the hole injection layer HIL, the first, second, and third emitting units EU1, EU2, and EU3, and the first, second, and third charge generation layers CGL1, CGL2, and CGL3 may be disposed on the upper surface and side surfaces of the tip portion T of the subpixel-defining layer 111.

A shape in which some of the constituent layers of the above-described intermediate layer 220 are discontinuous (or disconnected) near the air gap SPC may be similar to that described above with reference to FIG. 3.

As the hole injection layer HIL, the first, second, and third emitting units EU1, EU2, and EU3, and the first, second, and third charge generation layers CGL1, CGL2, and CGL3 are stacked on one another, the width of the air gap SPC may be reduced. For example, a distance W3″ between the tip portions T, which is the width of the air gap SPC, before the hole injection layer HIL is disposed may be greater than a width W4″ of the air gap SPC after the second charge generation layer CGL2 is disposed.

The fourth emitting unit EU4, the electron injection layer EIL, the opposite electrode 230, and the capping layer CPL may be disposed on the third charge generation layer CGL3. The fourth emitting unit EU4, the electron injection layer EIL, the opposite electrode 230, and the capping layer CPL may be connected in regions overlapping the trench TR.

A shape in which some of the constituent layers of the above-described intermediate layer 220 are continuous near the air gap SPC may be similar to that described above with reference to FIG. 3.

FIG. 12 is a magnified schematic cross-sectional view of a portion of the display apparatus 1 according to an embodiment.

The electrode layer HM may be disposed in the trench TR of the subpixel-defining layer 111. The electrode layer HM may have a semi-circular shape. For example, the electrode layer HM may have a shape of a semi-circle having a radius of R2.

The trench TR of the subpixel-defining layer 111 may have a semi-circular shape. For example, the trench TR may have a shape of a semi-circle having a radius of R1.

The radius R1 of the trench TR may be greater than the radius R2 of the electrode layer HM. Accordingly, the electrode layer HM may be spaced apart from the inner surface of the subpixel-defining layer 111 in which the trench TR is formed.

The outer surface of the subpixel-defining layer 111 may include a curved surface. For example, a portion of the outer surface of the subpixel-defining layer 111 may include an arc whose curvature is similar to that of the electrode layer HM and/or the trench TR. The thickness of the subpixel-defining layer 111 may not be constant.

The other features of the embodiment shown in FIG. 12 are the same as those described above with reference to FIG. 3.

According to an embodiment as described above, a display apparatus including a trench in which a Joule-heating wire is disposed between subpixel electrodes may be implemented. A charge generation layer and an organic layer removed by being heated with the Joule-heating wire may be re-coated in a space of the trench where the Joule-heating wire is not disposed. For example, the scope of the disclosure is not limited thereto.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display apparatus comprising:
a substrate;
a first subpixel electrode and a second subpixel electrode spaced apart from each other and disposed on the substrate;
a subpixel-defining layer disposed on the substrate, the subpixel-defining layer including:
openings that expose respective central portions of the first subpixel electrode and the second subpixel electrode, respectively, and
a trench disposed between the first subpixel electrode and the second subpixel electrode in plan view;
an electrode layer disposed in the trench to be spaced apart from side surfaces of the trench; and
a redistribution layer disposed between the electrode layer and the side surfaces of the trench to expose at least a portion of the electrode layer.

2. The display apparatus of claim 1, further comprising:
a plurality of emitting units disposed on the first subpixel electrode and the second subpixel electrode.

3. The display apparatus of claim 2, wherein at least one of the plurality of emitting units includes a first functional layer, a second functional layer, and emission layers disposed between the first functional layer and the second functional layer.

4. The display apparatus of claim 2, wherein at least one of the plurality of emitting units is connected in a region overlapping the trench.

5. The display apparatus of claim 2, further comprising:
one or more charge generation layers disposed between the plurality of emitting units.

6. The display apparatus of claim 5, wherein the one or more charge generation layers is disconnected in a region overlapping the trench.

7. The display apparatus of claim 5, wherein the one or more charge generation layers includes a negative charge generation layer and a positive charge generation layer.

8. The display apparatus of claim 2, further comprising:
an opposite electrode disposed on the plurality of emitting units.

9. The display apparatus of claim 1, wherein the subpixel-defining layer includes a tip portion protruding toward the trench.

10. The display apparatus of claim 1, wherein a width of the trench decreases in a direction.

11. The display apparatus of claim 1, wherein the trench surrounds each subpixel electrode in plan view.

12. A display apparatus comprising:
a substrate;
a first subpixel electrode and a second subpixel electrode spaced apart from each other and disposed on the substrate;
a subpixel-defining layer disposed on the substrate, the subpixel-defining layer including:
openings that expose respective central portions of the first subpixel electrode and the second subpixel electrode, respectively, and
a trench disposed between the first subpixel electrode and the second subpixel electrode in plan view;
an organic insulating layer disposed between the substrate and the subpixel-defining layer and including an opening overlapping the trench;
an electrode layer disposed in the openings to be spaced apart from side surfaces of the openings; and
a redistribution layer disposed between the electrode layer and the side surfaces of the openings to expose at least a portion of the electrode layer,
wherein the trench passes through the subpixel-defining layer.

13. A display apparatus comprising:
a substrate;
a plurality of subpixel electrodes spaced apart from each other and disposed on the substrate;
a subpixel-defining layer disposed on the substrate and including a plurality of openings respectively corresponding to the plurality of subpixel electrodes;
an emission element unit including a plurality of emission elements disposed on the plurality of subpixel electrodes; and
an electrode layer disposed on the subpixel-defining layer, wherein
the emission element unit includes a plurality of layers,
at least one of the plurality of layers is disposed to partially overlap the electrode layer in plan view, and
at least one of the plurality of layers has an opening exposing at least a portion of the electrode layer to outside.

14. The display apparatus of claim 13, wherein one of the plurality of layers of one of the plurality of emission elements is separated from one of the plurality of layers of another one of the plurality of emission elements.

15. The display apparatus of claim 13, wherein one of the plurality of layers of one of the plurality of emission elements is connected to one of the plurality of layers of another one of the plurality of emission elements in a region overlapping the electrode layer.

16. The display apparatus of claim 13, wherein the plurality of layers of the emission element unit are spaced apart from the electrode layer.

17. The display apparatus of claim 13, further comprising:
a redistribution layer that covers at least a portion of side surfaces of the electrode layer and exposes at least a portion of an upper surface of the electrode layer.

18. The display apparatus of claim 13, wherein
the subpixel-defining layer includes a trench, and
the electrode layer is disposed in the trench of the subpixel-defining layer.

19. The display apparatus of claim 13, wherein the electrode layer surrounds the plurality of emission elements of the emission element unit.

20. The display apparatus of claim 13, further comprising:
an opposite electrode disposed on the emission element unit and the electrode layer.
